(19) United States
(12) Patent Application Publication
(10) Pub. No.: US 2025/0055257 A1
(43) Pub. Date: Feb. 13, 2025

(54) VERTICAL CAVITY SURFACE EMITTING LASER DIODE (VCSEL) WITH CURRENT CONFINEMENT LAYER WITH PHOSPHORUS CONTENT

(71) Applicant: VISUAL PHOTONICS EPITAXY CO., LTD., Taoyuan City (TW)

(72) Inventors: Van-Truong Dai, Taoyuan City (TW); Van-Chien Nguyen, Taoyuan City (TW); Yu-Chung Chin, Taoyuan City (TW); Chao-Hsing Huang, Taoyuan City (TW)

(73) Assignee: VISUAL PHOTONICS EPITAXY CO., LTD., Taoyuan City (TW)

(21) Appl. No.: 18/928,666

(22) Filed: Oct. 28, 2024

Related U.S. Application Data
(63) Continuation-in-part of application No. 16/906,067, filed on Jun. 19, 2020.

(30) Foreign Application Priority Data
Jun. 21, 2019 (TW) 108121853
Apr. 12, 2024 (TW) 113113879

(51) Int. Cl. H01S 5/183; H01S 5/30

(52) U.S. Cl. CPC H01S 5/18311; H01S 5/1833; H01S 5/3095

(57) ABSTRACT

A vertical cavity surface emitting laser diode (VCSEL) includes a substrate, a lower Bragg reflector (DBR) layer, an active region, an upper Bragg reflector (DBR) layer, and a current confinement layer. The lower DBR layer is on the substrate. The active region is on the lower DBR layer on the active region. The current confinement layer is inside or outside the active region. When the current confinement layer comprises a compound containing phosphorus, such as AlAsP or AlGaAsP, and the phosphorus (P) content is within a specific range, the insulation rate of the current confinement layer will not be excessively fast to the point of being difficult to control. Additionally, the reproducibility of the aperture in the current confinement layer between batches of the VCSEL production is improved. Furthermore, the divergence angle of the VCSEL can be further reduced, thereby significantly enhancing the sensing capabilities of Lidar or 3D sensing.

### CROSS-REFERENCE TO RELATED APPLICATION

This application is a continuation-in-part of U.S. patent application Ser. No. 16/906,967 filed on Jun. 19, 2020, which claims priority to Taiwanese Application Serial No. 108121853, filed on Jun. 21, 2019, and this application claims priority under 35 U.S.C. § 119 (a) to patent application No. 113113879 filed in Taiwan, R.O.C. on Apr. 12, 2024. The entirety of the above-mentioned patent applications are incorporated herein by reference.

### TECHNICAL FIELD

The technical field relates to a vertical cavity surface emitting layer diode (VCSEL) with at least one current confinement layer, the current confinement layer comprises AlAsP or AlGaAsP compound, wherein the phosphorus content is within a specific range. In this configuration, the insulation rate of the current confinement layer is controlled such that it does not become excessively fast to the point of being difficult to manage. Additionally, the reproducibility of the aperture in the current confinement layer across different VCSEL production batches is improved. Furthermore, the divergence angle of the VCSEL is minimized. This invention is distinct from other technologies related to general semiconductor lasers or other light-emitting diodes (LEDs) that do not address the specific issues of current confinement and aperture reproducibility in the context of VCSELs.

### BACKGROUND

Laser light sources such as vertical cavity surface emitting layer diodes (VCSELs) are now commonly used as light sources for 3D sensing or optical communications. If the optical output power and power conversion efficiency of a VCSEL can be further improved, the 3D sensing or optical communications can save more power or reduce the chip area to reduce cost. In addition, the application of the VCSEL can also be extended to light detection and ranging (LiDAR), Virtual Reality (VR), Augmented Reality (AR), Direct Time-of-Flight (dTOF) sensors or other applications.

The main feature of a VCSEL is that it emits light generally perpendicular to its wafer surface. Generally, epitaxial growth methods such as metal organic chemical vapor deposition (MOCVD) or molecular beam epitaxy (MBE) can be used to form an epitaxial structure having a multi-layer structure on the substrate.

Optoelectronic devices can be broadly categorized into light-emitting elements, such as light-emitting diodes (LEDs) and general laser diodes, and optoelectronic conversion elements, such as solar cells. LEDs and solar cells typically do not require a selectively oxidized layer with apertures, and therefore, do not face the specific challenges of optical confinement, current confinement, or aperture reproducibility.

In contrast, laser diodes that incorporate selectively oxidized layers with apertures do face these issues. Existing technologies have predominantly focused on aspects such as the relative position of the selectively oxidized layer to the active region or the thickness of the oxidized layer itself. However, these approaches often overlook other critical factors that significantly impact the performance and manufacturing yield of Vertical-Cavity Surface-Emitting Lasers (VCSELs).

VCSELs play a crucial role as the primary light source in optical communication and optical sensing systems. The inability to address the challenges related to VCSEL characteristics and aperture reproducibility would severely limit the characteristics and reliability of these systems. Therefore, addressing these factors is essential to enhance the performance and expand the application potential of VCSELs in advanced optoelectronic systems.

Some people believe that enlarging the uppermost optical aperture (i.e., OA) directly impacts the beam divergence angle. However, merely enlarging the uppermost OA to reduce the beam's divergence angle has limited characteristics in practical applications and may even be counterproductive. This perspective completely overlooks the fact that the uppermost OA itself serves as a current confinement structure, ensuring that the current is concentrated in the center of the active region. Enlarging the OA would compromise the current confinement effect, leading to uneven carrier distribution and affecting the more critical optical gain of the VCSEL.

### SUMMARY

From the above, it is clear that the goal of reducing the divergence angle of the VCSEL is not only unmet, but the optical gain of the VCSEL is also affected. Therefore, it is necessary to propose a specific epitaxial structure and material system that does not affect the optical gain of the VCSEL while effectively reducing the divergence angle and ensuring high reproducibility of the OA(s).

In some embodiments, the material of the current confinement layer has the characteristic of being easily oxidized. Preferably, the material of the current confinement layer contains aluminum or other easily oxidized materials, such as AlGaAs, AlGaAsP, AlAs, AlAsP, AlAsSb or AlAsBi. Specifically, when the current confinement layer of the VCSEL comprises a compound containing phosphorus (P) such as AlAsP (or AlGaAsP), a single current confinement layer can be used to achieve a smaller divergence angle for the VCSEL. Furthermore, the reproducibility of the OA(s) in the current confinement layer between various batches of the VCSEL production is improved because the insulation process of the current confinement layer does not proceed too rapidly; specifically, the oxidation rate of the current confinement layer is not too fast.

In some embodiments, a vertical cavity surface emitting laser diode (VCSEL) is provided. The VCSEL comprises a substrate, a lower DBR layer, an active region, an upper DBR layer, and a current confinement layer. The lower DBR layer is on the substrate. The active region is on the lower DBR layer and comprises two active layers. The upper DBR layer is on the active region. The current confinement layer is between the two active layers and comprises an AlAsP compound or an AlGaAsP compound, wherein the current confinement layer has an insulating region and a non-insulating region surrounded by the insulating region, wherein a molar percentage of a phosphorus content in the compound containing phosphorus (P) is greater than 0% and less than or equal to 30%.

In some embodiments, a vertical cavity surface emitting laser diode (VCSEL) is provided. The VCSEL comprises a substrate, a lower DBR layer, an active region, an upper DBR layer, and a current confinement layer. The lower DBR layer is on the substrate. The active region is on the lower DBR layer. The upper DBR layer is on the active region. The current confinement layer is outside the active region and comprises an AlAsP compound or an AlGaAsP compound, wherein the current confinement layer has an insulating region and a non-insulating region surrounded by the insulating region, wherein a molar percentage of a phosphorus content in the compound containing phosphorus (P) is greater than 0% and less than or equal to 30%.

### BRIEF DESCRIPTION OF THE DRAWINGS

FIG. 1a is a schematic diagram showing that one of two current confinement layers is disposed inside the active region according to one embodiment of the present disclosure, wherein the optical aperture (OA) of the current confinement layer outside the active region is smaller than that of the current confinement layer inside the active region.

FIG. 1b is a schematic diagram showing that one of two current confinement layers is disposed inside the active region according to one embodiment of the present disclosure, wherein the OA of the current confinement layer outside the active region is greater than that of the current confinement layer inside the active region.

FIG. 1c is a schematic diagram showing that one of two current confinement layers is disposed inside the active region according to one embodiment of the present disclosure, wherein the OAs of the two current confinement layers are approximately equal or close to each other.

FIG. 1d is a detailed schematic diagram showing a possible structure of the active region of FIG. 1a.

FIG. 2 is a schematic diagram showing that the number of active layers is greater than the number of current confinement layers according to one embodiment of the present disclosure.

FIG. 3a shows a schematic diagram of a VCSEL including three current confinement layers and two active layers according to one embodiment of the present disclosure, wherein the OAs of the three current confinement layers are not equal.

FIG. 3b shows a schematic diagram of a VCSEL including three current confinement layers and two active layers, wherein the OAs of the three current confinement layers are approximately equal or close to each other.

FIG. 3c is a detailed schematic diagram showing a possible structure of the active region of FIG. 3a.

FIG. 4a shows a schematic diagram of a VCSEL including three current confinement layers and three active layers according to one embodiment of the present disclosure, wherein the OAs of the three current confinement layers are not equal.

FIG. 4b shows a schematic diagram of a VCSEL including three current confinement layers and three active layers according to one embodiment of the present disclosure, wherein the areas of the second OA and the third OA are approximately equal or close to each other, and the first OA outside the active region is smaller than the second OA or the third OA inside the active region.

FIG. 4c shows a schematic diagram of a VCSEL including three current confinement layers and three active layers according to one embodiment of the present disclosure, wherein the OAs of the three current confinement layers are approximately equal or close to each other.

FIG. 5a shows a schematic diagram of a VCSEL including four current confinement layers and three active layers according to one embodiment of the present disclosure, wherein the relationship among the first OA to the fourth OA is from small to large.

FIG. 5b shows a schematic diagram of a VCSEL including four current confinement layers and three active layers according to one embodiment of the present disclosure, wherein the relationship among the first OA to the fourth OA is from large to small.

FIG. 6a shows a schematic diagram of a VCSEL including five current confinement layers and five active layers according to one embodiment of the present disclosure, wherein the OAs of the five current confinement layers are not equal.

FIG. 6b shows a schematic diagram of a VCSEL including five current confinement layers and five active layers according to one embodiment of the present disclosure, wherein the OAs of four current confinement layers inside the active region are approximately equal or close to each other, and the OA of the current confinement layer outside the active region is smaller than the OAs of the current confinement layers inside the active region.

FIG. 6c shows a schematic diagram of a VCSEL including five current confinement layers and five active layers according to one embodiment of the present disclosure, wherein the fourth OA and the fifth OA are larger than the second OA and the third OA, and the second OA and the third OA are larger than the first OA.

FIG. 7 illustrates a schematic view of a VCSEL according to some embodiments.

FIG. 8 illustrates a schematic view of a VCSEL according to some embodiments.

FIG. 9 illustrates a schematic view of a VCSEL according to some embodiments.

FIG. 10 illustrates a schematic view of a VCSEL according to some embodiments.

FIG. 11 illustrates oxidation rates of the first current confinement layer shown in FIG. 7 (which comprises an AlAs₁₋ₓPₓ compound) and the traditional current confinement layer (which comprises an AlAs compound).

FIG. 12 illustrates a far field profile of the traditional VCSEL (with its current confinement layer containing an AlGaAs compound) based on the structure of the VCSEL shown in FIG. 7.

FIG. 13a illustrates a far field profile of the VCSEL shown in FIG. 7 (with its current confinement layer containing an AlAs₁₋ₓPₓ compound, and x=0.02).

FIG. 13b illustrates a far field profile of the VCSEL shown in FIG. 7 (with its current confinement layer containing an AlAs₁₋ₓPₓ compound, and x=0.04).

FIG. 13c illustrates a far field profile of the VCSEL shown in FIG. 7 (with its current confinement layer containing an AlAs₁₋ₓPₓ compound, and x=0.06).

FIG. 13d illustrates a far field profile of the VCSEL shown in FIG. 7 (with its current confinement layer containing an AlAs₁₋ₓPₓ x compound, and x=0.08).

FIG. 13e illustrates a far field profile of the VCSEL shown in FIG. 7 (with its current confinement layer containing an AlAs₁₋ₓPₓ compound and x=0.10).

FIG. 13f illustrates a far field profile of the VCSEL shown in FIG. 7 (with its current confinement layer containing an AlAs₁₋ₓPₓ compound and x=0.12).

FIG. 14 illustrates a far field profile of the traditional VCSEL (with its current confinement layer containing an AlAs compound) based on the structure of the VCSEL shown in FIG. 7.

FIG. 15 illustrates a far field profile of the traditional VCSEL (with its current confinement layer containing an AlGaAs compound (for example, an Al_{1-y}Ga_{y}As compound and y=0.02)) based on the structure of the VCSEL shown in FIG. 1c.

FIG. 16 illustrates a far field profile of the VCSEL shown in FIG. 1c (with its current confinement layer containing an AlAs₁₋ₓPₓ compound and x=0.04).

FIG. 17 illustrates a far field profile of the traditional VCSEL (with its current confinement layer containing an AlGaAs compound (for example, an Al_{1-y}Ga_{y}As compound and y=0.02)) based on the structure of the VCSEL shown in FIG. 10.

FIG. 18 illustrates a far field profile of the VCSEL shown in FIG. 10 (with its current confinement layers containing AlAs₁₋ₓPₓ compounds and x=0.04).

### DETAILED DESCRIPTION

The embodiment of the present disclosure is described in detail below with reference to the drawings and element symbols, such that persons skilled in the art is able to implement the present application after understanding the specification of the present disclosure.

Specific examples of components and arrangements are described below to simplify the present disclosure. These are, of course, merely examples and they are not intended to limit the scope of the present disclosure. In the present disclosure, for example, when a layer formed above or on another layer, it may include an exemplary embodiment in which the layer is in direct contact with the another layer, or it may include an exemplary embodiment in which other devices or epitaxial layers are formed between thereof, such that the layer is not in direct contact with the another layer. In addition, repeated reference numerals and/or notations may be used in different embodiments, these repetitions are only used to describe some embodiments simply and clearly, and do not represent a specific relationship between the different embodiments and/or structures discussed.

Further, spatially relative terms, such as “underlying,” “below,” “lower,” “overlying,” “above,” “upper” and the like, may be used herein for ease of description to describe one device or feature's relationship to another device(s) or feature(s) as illustrated in the figures and/or drawings. The spatially relative terms are intended to encompass different orientations of the device in use or operation in addition to the orientation depicted in the figures and/or drawings.

Moreover, certain terminology has been used to describe embodiments of the present disclosure. For example, the terms “one embodiment,” “an embodiment,” and “some embodiments” mean that a particular feature, structure or characteristic described in connection with the embodiment is included in at least one embodiment of the present disclosure. Therefore, it is emphasized and should be appreciated that two or more references to “an embodiment” or “one embodiment” or “an alternative embodiment” in various portions of the present disclosure are not necessarily all referring to the same embodiment.

Furthermore, the particular features, structures or characteristics may be combined in any suitable manner in one or more embodiments of the present disclosure. Further, for the terms “including”, “having”, “with”, “wherein” or the foregoing transformations used herein, these terms are similar to the term “comprising” to include corresponding features.

In addition, a “layer” may be a single layer or a plurality of layers; and “a portion” of an epitaxial layer may be one layer of the epitaxial layer or a plurality of adjacent layers.

In the prior art, the laser diode can be optionally provided with a buffer layer according to actual needs, and in some embodiments, the materials of the buffer and the substrate may be the same. Whether the buffer is provided is not substantially related to the technical characteristics to be described in the following embodiments and the effects to be provided. Accordingly, for the sake of a brief explanation, the following embodiments are only described with a laser diode having a buffer layer, and no further description is given to a laser without a buffer layer; that is, the following embodiments can also be applied by replacing a laser diode without a buffer.

A vertical cavity surface emitting laser diode (VCSEL) is provided in the present disclosure. The typical manufacturing method of a VCSEL is to epitaxially grow a multi-layer structure on a substrate, and the finished product of a VCSEL is not necessary to have a substrate. That is, the VCSEL can retain the substrate or remove the substrate. The multi-layer structure includes an active region, and the active region includes one or a plurality of active layers. If the active region includes a plurality of active layers, a tunnel junction is arranged between every two adjacent active layers.

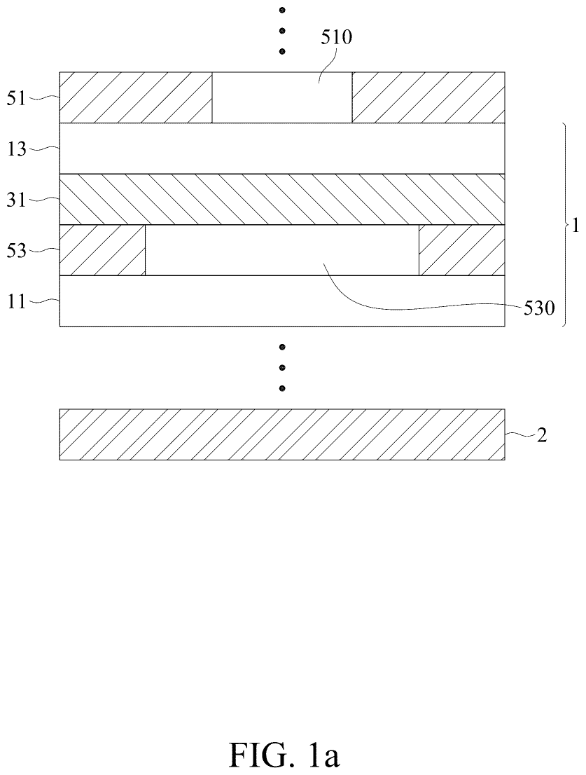

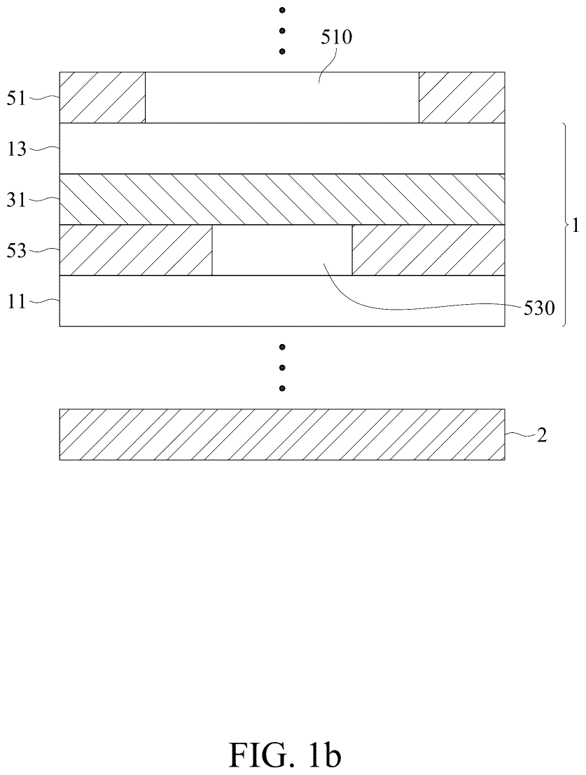

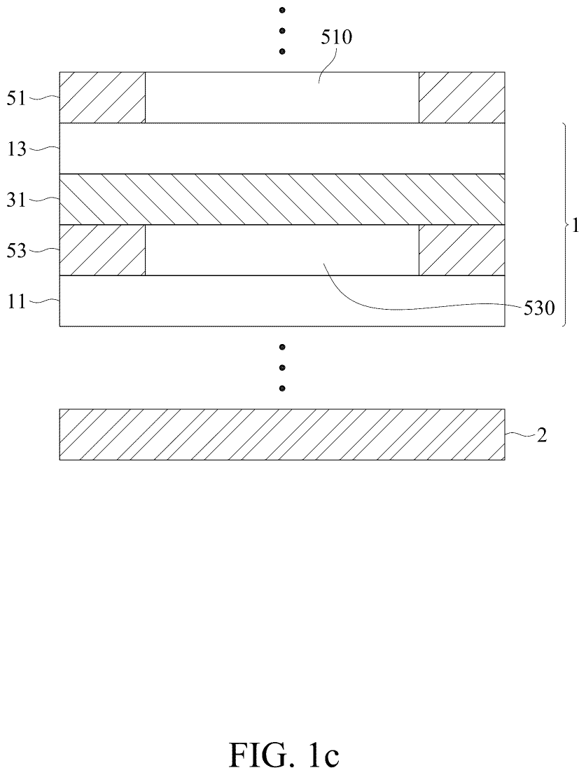

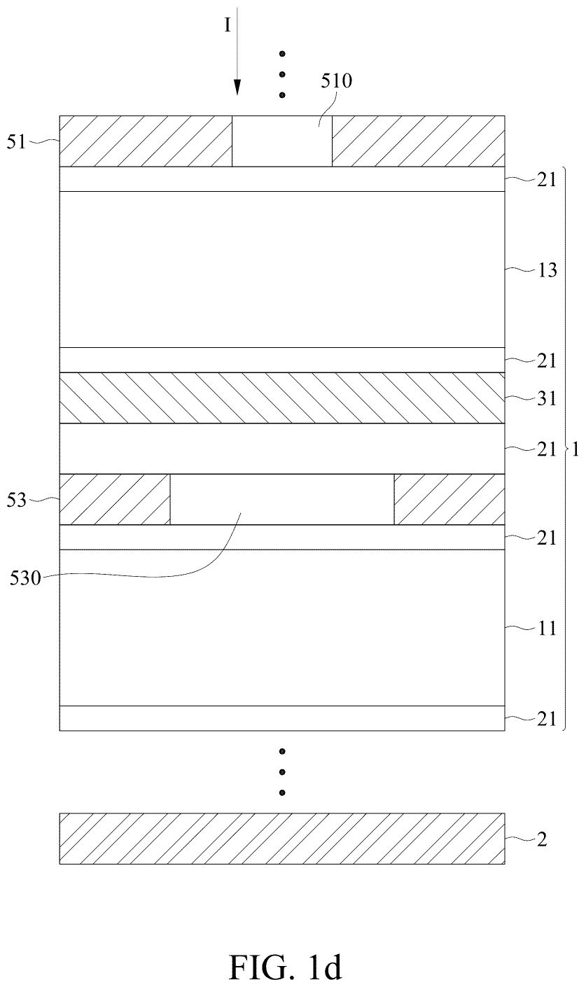

Each embodiment of the present disclosure is to provide two or more current confinement layers in the multi-layer structure. Each current confinement layer has at least one optical aperture (OA). The OA is the uninsulated portion of each current confinement layer, while the insulated portion of each current confinement layer (as shown by the diagonal lines of the current confinement layer 51 of FIG. 1a) should be understood as the portion with a high resistance of the current confinement layer.

The number of current confinement layers may be three, four, five or more layers. In different embodiments, the disposition or combination of current confinement layers will be different. Therefore, in order to distinguishing the position of each current confinement layer, in the case of two current confinement layers, one of the current confinement layers is called the first current confinement layer, and the other one is called the second current confinement layer. In the case of three or more current confinement layers, they are called the first current confinement layer, the second current confinement layer, the third current confinement layer, and so on. Similarly, in order to distinguish the position of each active layer of the multiple active layers in the VCSEL, the active layers of the multiple active layers are called the first active layer, the second active layer, the third active layer . . . to the Nth active layer, and so on.

In order to simplify the drawings, most of the drawings only show epitaxial layers such as active layers, tunnel junctions and current confinement layers, etc., the other epitaxial layers such as upper DBR layers, lower DBR layers, spacer layers, ohmic contact layers, etc. are not displayed even if these epitaxial layers are a necessary or preferred structure of a VCSEL. The spacer layer is generally formed above and/or below the active layer, current confinement layer, tunnel junction or other epitaxial layers. The spacer layer may be selectively disposed according to actual needs, and the material, material composition, thickness, doping and doping concentration of each spacer layer may also be adjusted appropriately in accordance with actual needs.

The following uses some representative embodiments to explain how two or more current confinement layers are specifically arranged in a VCSEL.

### Embodiment 1

In terms of the main structure shown in FIG. 1a, FIG. 1b, and FIG. 1c, the first current confinement layer 51 with the first OA 510 is disposed on the active region 1. The tunnel junction 31 and the second current confinement layer 53 with the second OA 530 are disposed between the first active layer 11 and the second active layer 13 in the active region 1. The tunnel junction 31 is between the first current confinement layer 51 and the second current confinement layer 53.

According to the structure of FIG. 1a, since the tunnel junction 31, the second current confinement layer 53 and the first active layer 11 are sequentially under the second active layer 13, in this configuration, when current flows from the first OA 510 and into the first active layer 11 through the second OA 530. The epitaxial layer above the first current confinement layer 51 is mainly composed of a P-type epitaxial layer. If the epitaxial layer above the first current confinement layer 51 further includes an N-type epitaxial layer (not shown), the N-type epitaxial layer and the first current confinement layer 51 can be connected in series with the tunnel junction or form an indirect contact through the tunnel junction.

In terms of OA areas (i.e., opening areas), the OA area of the first OA is not equal to the OA area of the second OA, as shown in FIG. 1a and FIG. 1b. As shown in FIG. 1c, when the OA areas of the first OA 510 and the second OA 530 are sufficiently large, the OA areas of the first OA 510 and the second OA 530 may be substantially equal or close to each other.

FIG. 1d is the detailed structure of FIG. 1a. In FIG. 1d, the spacer layer 21 is provided above and below the active layers 11, 13, the current confinement layers 53 (51) and the tunnel junction 31. Current I mainly passes through the first OA 510 for carrier confinement and/or optical confinement, the second active layer 13 for emitting light, the tunnel junction 31 for carrier recycling or connecting two active layers, the second OA 530 for carrier confinement and/or optical confinement, and the first active layer 11 for emitting light.

After the current I enters the second active layer 13 from the first OA 510, the current I flowing through the second active layer 13 and the tunnel junction 31 becomes less spreading, such that the carrier confinement of the second active layer 13 becomes better. After the current I passes through the second OA 530 of the second current confinement layer 53, the current I is more easily confined to the area of the first active layer 11 corresponding to the second OA 530, such that the carrier and/or optical confinement of the first active layer 11 and the second active layer 13 can be significantly improved, thereby improving the optical output power, slope efficiency, or power conversion efficiency (PCE) of the VCSEL.

By disposing the second current confinement layer between two active layers, the carrier confinement effect of the second current confinement layer can act on the second active layer and the first active layer above and below the second current confinement layer. In this way, not only can the carrier confinement and/or optical confinement of the first active layer be improved, but also the carrier confinement and/or optical confinement of the second active layer can be further improved. As such, the optical output power of the VCSEL can be significantly increased as the number of active layers is increased, and slope efficiency or the PCE of the VCSEL can also be significantly improved as the number of active layers is increased.

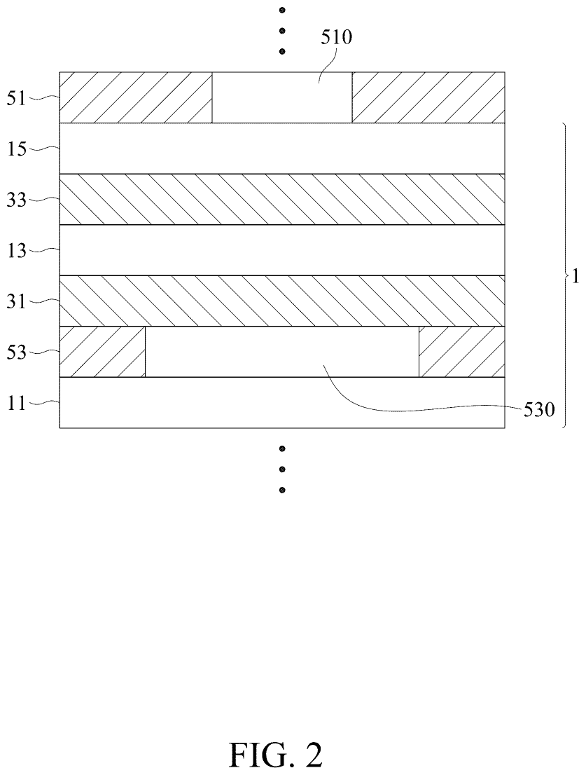

In some embodiments, the number of current confinement layers may be less than the number of active layers. As shown in FIG. 2, the number of current confinement layers may be two layers. The number of active layers in the active region may be three layers, but not limited thereto. The number of active layers may be four or more layers. If the optical output power, slope efficiency or PCE of the VCSEL needs to be further improved, the number of current confinement layers may be the same as that of the active layers. The number of current confinement layers may also be more than the number of active layers. For example, the number of current confinement layers may be more than the number of active layers by one more layer or more than two layers, but the total resistance of all current confinement layers cannot be too large, otherwise it may affect the performance or PCE of the VCSEL.

Another factor that determines the resistance of the current confinement layer is the area of the OA of the current confinement layer. In principle, the OA areas of two OAs or the OA areas of the OAs may be unequal. However, if the OA areas of two OAs or the OA areas of the OAs are large enough, since the resistance is small, the OA areas of two OAs or the OA areas of the OAs may still be approximately equal or close to each other.

In FIG. 1a and FIG. 1b, the OA areas of the first OA and the second OA are not equal. The ratio of the OA area of the first OA to the OA area of the second OA may be between 0.1 and 10 (excluding the ratio of 1). The total resistance of the current confinement layers is not too large so as not to significantly affect the performance or PCE of the VCSEL. Preferably, the ratio of the OA area of the first OA to the OA area of the second OA may be between 0.2 and 5, between 0.3 and 3.3, between 0.5 and 2, between 0.54 and 1.85 or between 0.6 and 1.6. In addition to maintaining better carrier confinement and/or optical confinement, the total resistance of two current confinement layers is relatively small so as to help improve the performance or PCE of the VCSEL. The specific ratio of the area of the first OA to the area of the second OA is 0.5, 0.6, 0.7, 0.8, 0.9, 1.0, 1.1, 1.2, 1.3, 1.4, 1.5, 1.6, 1.7, 1.8, 1.9 or 2.0.

In the case where the areas of the first OA and the second OA are sufficiently large, since the resistance of the first current confinement layer and the second current confinement layer are relatively small, the total resistance of both thereof is not easily too large. Accordingly, the areas of the first OA and the second OA may be approximately equal or even equal. For example, if the areas of the first OA and the second OA are not less than 30 μm², the area of the first OA may be approximately equal to, nearly equal, or even exactly equal to that of the second OA. In some embodiments, the smaller area of each current confinement layer may also be greater than 40 μm² or 50 μm².

According to the previous paragraph, if the total resistance of current confinement layers can be appropriately reduced, it is easy to maintain or improve the PCE of the VCSEL, and the first active layer and the second active layer may also have better carrier confinement and optical confinement, thereby improving the performance, slope efficiency or PCE of the VCSEL. The VCSEL may be a top-emitting VCSEL or a bottom-emitting VCSEL.

In the case where the areas of both the first OA and the second OA are sufficiently large, preferably, the ratio of the area of the first OA to the area of the second OA is X, where 0.3≤X≤1. Therefore, in one case, the areas of the first OA and the second OA are approximately equal or close to each other; that is, the ratio of the area of the first OA to the area of the second OA is close to or may be exactly 1 (X≈1 or X=1). In the other case, when the areas of the first OA and the second OA are different, the ratio of the area of the first OA to the area of the second OA is greater than or equal to 0.3 and less than 1 (0.3≤X<1). The smaller area between the first OA and the second OA is the numerator of the ratio, and the larger area between both thereof is the denominator of the ratio.

### Embodiment 2

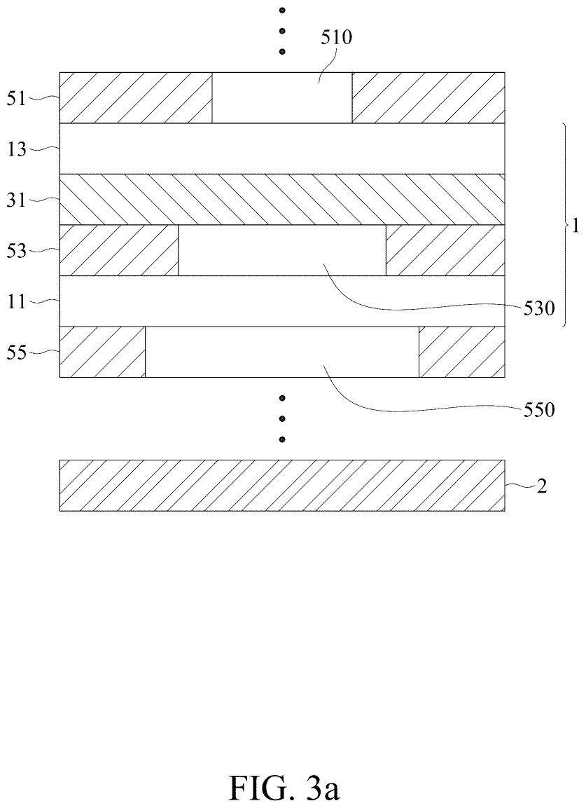

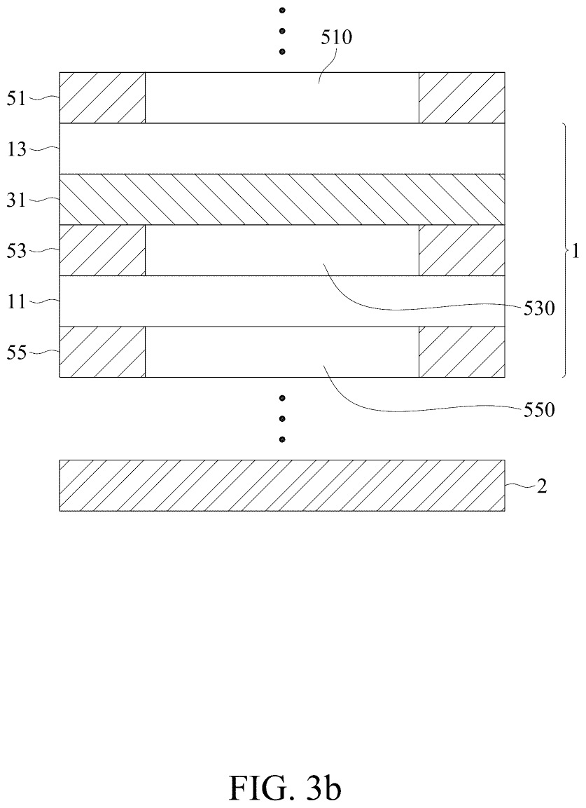

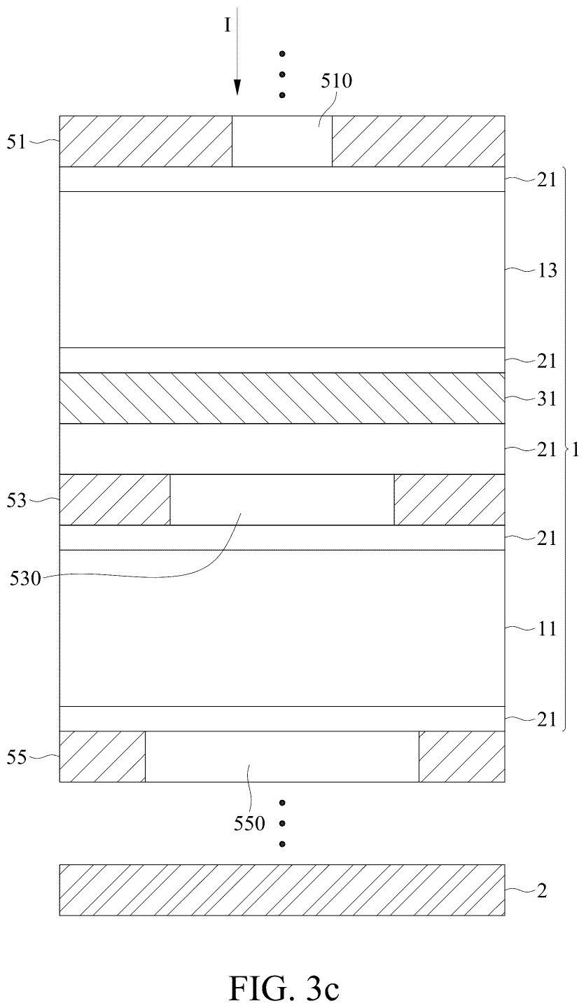

As shown in FIG. 3a, the VCSEL includes three current confinement layers 51, 53, 55 and two active layers 11, 13. The areas of the three current confinement layers 51, 53, 55 are not equal to each other, and the areas of the first, second and third OAs are a small area, a medium area and a large area, respectively. The structure shown in FIG. 3a is only an example. The areas of the first, second and third OAs may also be a large area, a medium area and a small area, respectively, may be a small area, a medium area and a medium area, respectively, or may be various other appropriate combinations. Preferably, the ratio of the area of the first OA to the area of the second OA, the ratio of the area of the second OA to the area of the third OA or the ratio of the area of the third OA to the first OA may be between 0.2 and 5, between 0.3 and 3.3, between 0.5 and 2, between 0.54 and 1.85 or between 0.6 and 1.6. The specific ratio thereof may be 0.5, 0.6, 0.7, 0.8, 0.9, 1.0, 1.1, 1.2, 1.3, 1.4, 1.5, 1.6, 1.7, 1.8, 1.9 or 2.0.

As long as the carrier confinement and/or optical confinement of the active layer as well as the PCE of the VCSEL are not significantly affected, the area of OA of the current confinement layer outside the active region 1 may be as large as possible, as shown in the third OA 550 of FIG. 3a. In the VCSEL provided with multiple current confinement layers, the total resistance of current confinement layers is less likely to be too large such that the performance of the VCSEL are also less likely to be affected.

### Embodiment 3

In the case where the VCSEL includes three current confinement layers or even more current confinement layers, if the areas of some OAs or all OAs are large enough, that is, the total resistance of the current confinement layers will not be too large, the areas of some OAs or all OAs may not be equal to each other, and two or each of some OAs or all OAs may also be approximately equal or close to each other.

Taking FIG. 3b as an example, if the smallest area among the first, second and third Oas is greater than 30 μm² (40 μm²/50 μm²), the areas thereof may even be equal to each other. In principle, as long as the total resistance of the current confinement layers does not significantly affect the PCE of the VCSEL, one or some of the current confinement layers may be less than 30 μm² (40 μm²/50 μm²).

Further, two of the first, second and third OAs have a ratio X, where 0.3≤X≤1. Accordingly, the areas thereof may be equivalent, that is, the ratio X is close to or may be exactly equal to 1 (X≈1 or X=1). When the areas of two thereof or all three OAs are different, the ratio X is greater than or equal to 0.3 and less than 1 (0.3≤X<1). In such case, the smaller area among two thereof is numerator of the ratio.

FIG. 3c is the detailed structure of FIG. 3a. In FIG. 3c, a spacer layer 21 is provided above and below the active layers 11, 13, the tunnel junction 31 and the current confinements 51, 53, 55, but FIG. 3c is only an example. Other modified or derived implementation structures may also be included in the present disclosure. The main structures in FIG. 3b and FIG. 3a are also the same. In FIG. 3b, the spacer layer may also be provided in the foregoing manner.

### Embodiment 4

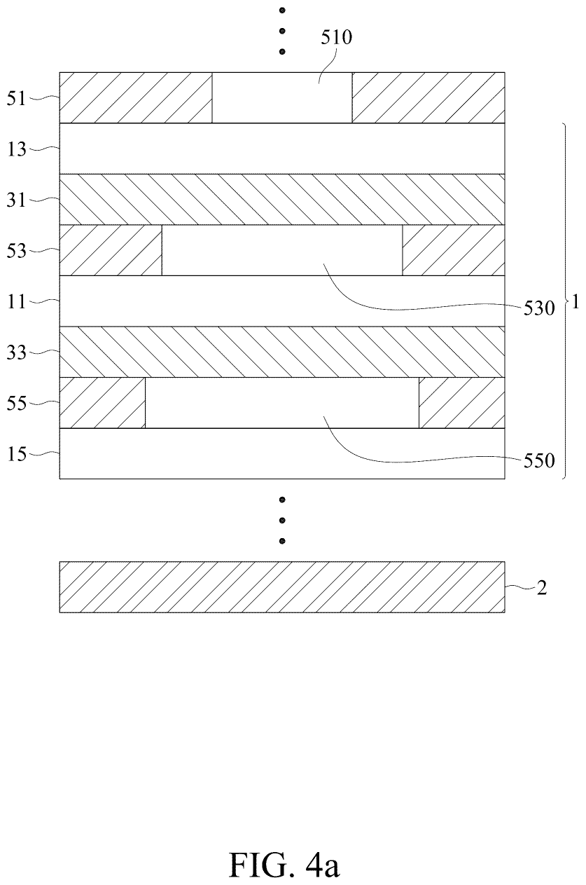

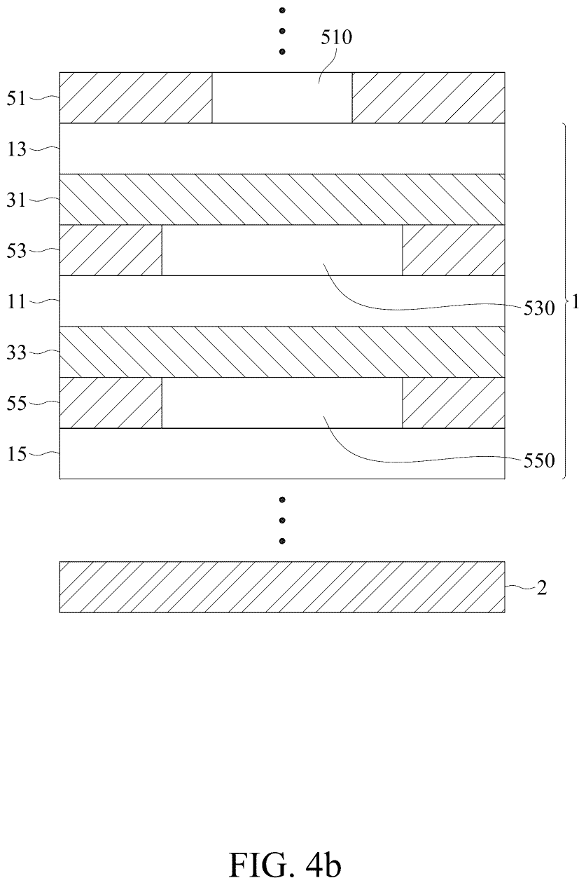

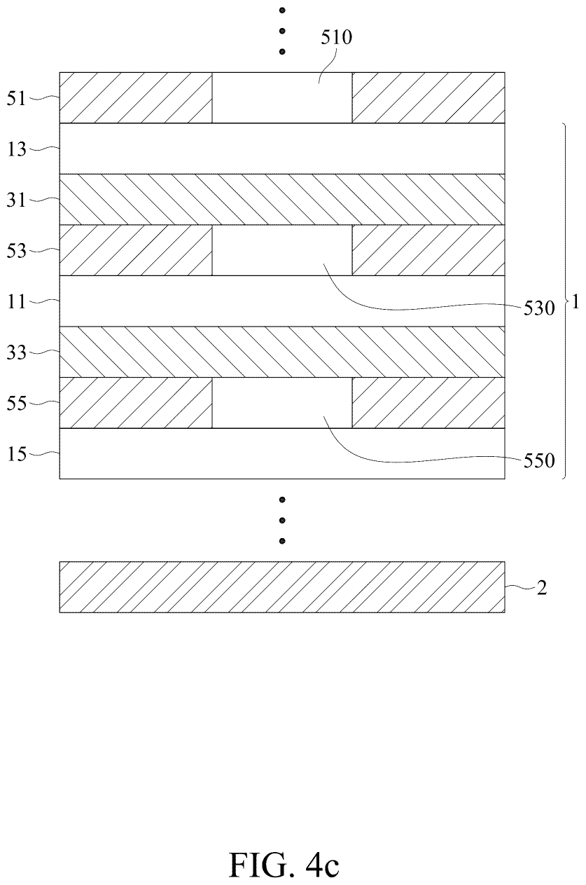

As shown in FIG. 4a, FIG. 4a is based on FIG. 3a, and further includes a third active layer 15 and a tunnel junction 33. The third active layer 15 is disposed below the first active layer 11, and a tunnel junction 33 and a third current confinement layer 55 are provided between the third active layer 15 and the first active layer 11. In addition, a tunnel junction 31 is disposed between the first current confinement layer 51 and the second current confinement layer 53, while the tunnel junction 33 is provided between the second current confinement layer 53 and the third current confinement layer 55.

In FIG. 4a, the areas of the first OA 510, the second OA 530 and the third OA 550 are a small area, a medium area and a large area, respectively. The structure shown in FIG. 4a is only an example. The areas of the first OA 510, the second OA 530 and the third OA 550 may also be a large area, a medium area and a small area, respectively, may be a small area, a large area and a medium area, or may be various other appropriate combinations. Alternatively, as shown in FIG. 4b, the area of the first OA 510 is small, and the areas of the second OA 530 and the third OA 550 are almost equal and larger than the area of the first OA 510. On the other hand, as shown in FIG. 4c, the areas of the first OA 510, the second OA 530 and the third OA 550 are approximately equal or equal.

A spacer or other epitaxial layers may further be provided above and/or below the active layer, current confinement layer or tunnel junction in FIG. 4a to FIG. 4c in accordance with actual needs.

### Embodiment 5

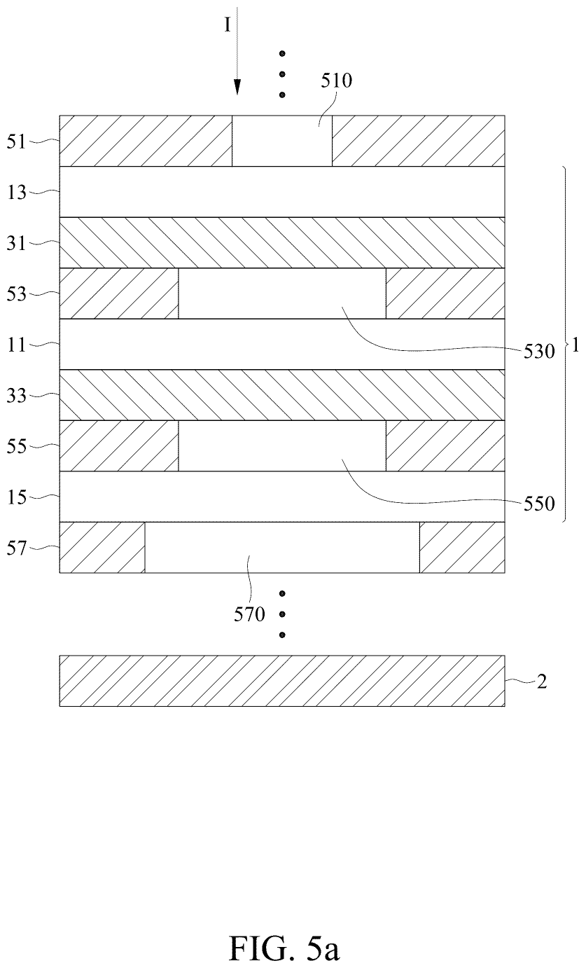

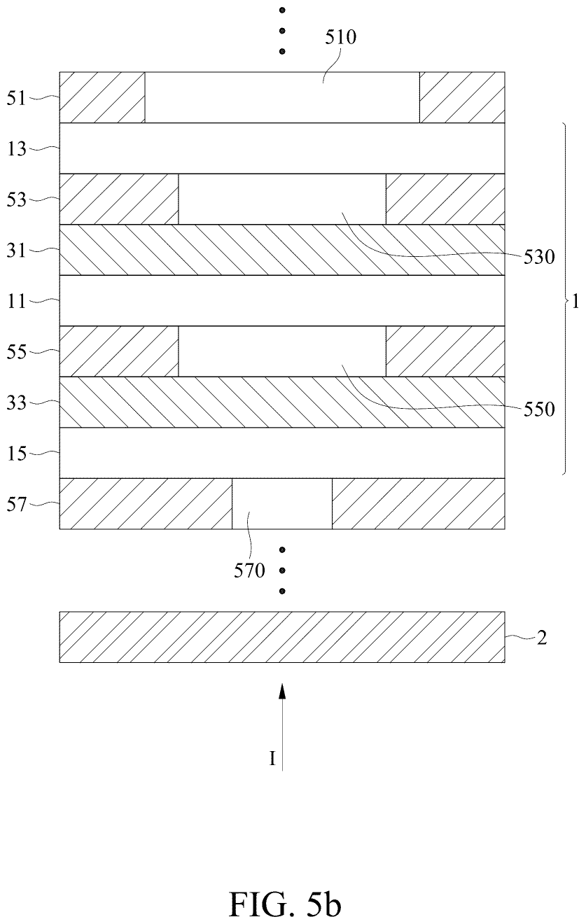

As shown in FIG. 5a, the VCSEL includes current confinement layers 51, 57 and an active region 1, and the active region 1 includes active layers 11, 13, 15, current confinement layers 53, 55, and tunnel junctions 31, 33. The first current confinement layer 51 and the fourth current confinement layer 57 are disposed above and below the active region 1. The tunnel junction 31 is provided between the first current confinement layer 51 and the second current confinement layer 53, and the tunnel junction 33 is provided between the second current confinement layer 53 and the third current confinement layer 55.

According to the arrangement relationship between the third current confinement layer 55 and the tunnel junction 33 of FIG. 5a, when current flows from the first OA 510, an epitaxial layer above the first current confinement layer 51 is mainly composed of a P-type epitaxial layer. If the epitaxial layer above the first current confinement layer 51 further includes an N-type epitaxial layer, a serial connection or indirect connection may be formed through a tunnel junction between the N-type epitaxial layer and the first current confinement layer 51.

As shown in FIG. 5b, the VCSEL includes current confinement layers 51, 57 and an active region 1, and the active region 1 includes active layers 11, 13, 15, current confinement layers 53, 55, and tunnel junctions 31, 33. The first current confinement layer 51 and the fourth current confinement layer 57 are disposed above and below the active region 1. According to the arrangement relationship between the tunnel junction 33 and the third current confinement layer 55 or the arrangement relationship between the tunnel junction 31 and the second current confinement layer 53 of FIG. 5b, current flows from the fourth OA 570. An epitaxial layer below the fourth current confinement layer 57 is mainly composed of a P-type epitaxial layer. If the epitaxial layer below the fourth current confinement layer 57 further includes an N-type epitaxial layer, a serial connection or indirect connection may be formed through a tunnel junction between the N-type epitaxial layer and the fourth current confinement layer 57.

In a modified embodiment, the area of OA of the current confinement layer outside the active region 1 may be very large, as shown in the fourth current confinement layer 57 (below the active region 1) of FIG. 5a or the first current confinement layer 51 (above the active region 1) of FIG. 5b. In such case, the total resistance of each current confinement layer is less likely to be too large, and the performance of the VCSEL is less likely to be affected.

A spacer or other epitaxial layers may further be provided above and/or below the active layer, current confinement layer and/or tunnel junction layer in FIG. 5a or FIG. 5b according to actual needs.

### Embodiment 6

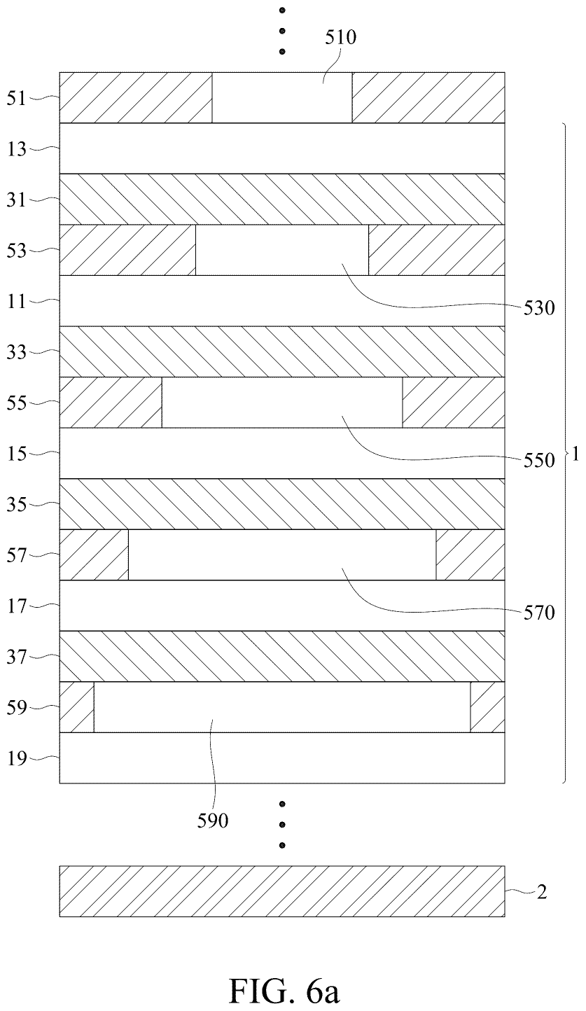

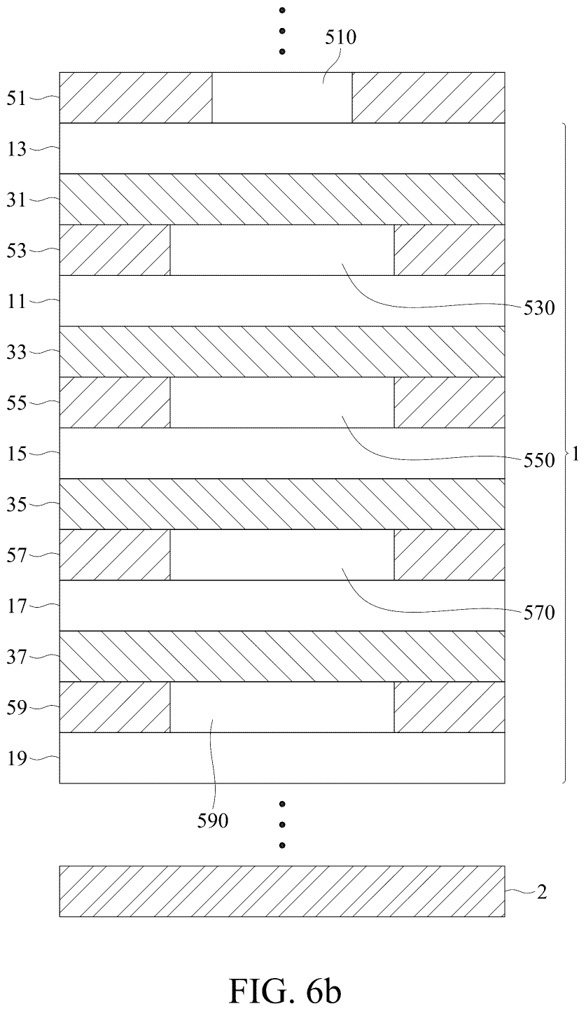

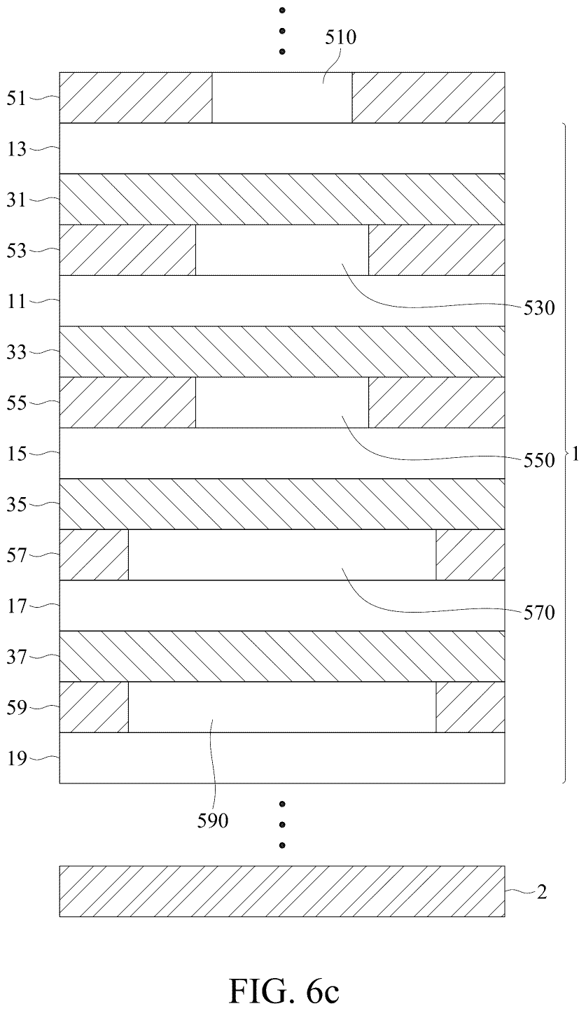

FIG. 6a, FIG. 6b, and FIG. 6c show a VCSEL including five current confinement layers and five active layers. In FIG. 6a, the areas of the first OA 510, the second OA 530, the third OA 550, the fourth OA 570 and the fifth OA 590 are not equal to each other. The area of the first OA 510 is the smallest and the area of the fifth OA 590 is the largest. The area of the second OA 530 is larger than that of the first OA 510, the area of the third OA 550 is larger than that of the second OA 530, and the area of the fourth OA 570 is larger than that of the third OA 550. The structure shown in FIG. 6a is only an example. The areas of the first OA to the fifth OA may be various other appropriate combinations.

In FIG. 6b, the area of the first OA 510 above the active region 1 is the smallest, and the areas of the second OA 530, the third OA 550, the fourth OA 570 and the fifth OA 590 in the active region 1 are approximately equal or close to each other. The structure shown in FIG. 6b is only an example. The areas of the first OA 510 through the fifth OA 590 may also be various other suitable combinations.

In FIG. 6c, the area of the first OA 510 is relatively smallest, the areas of the fourth OA 570 and the fifth OA 590 are relatively large, and the areas of the second OA 530 and the third OA 550 are larger than the area of the first OA 510 but smaller than the area of the fourth OA 570 or the fifth OA 590.

A spacer or other epitaxial layers may further be provided above and/or below the active layer, current confinement layer and/or tunnel junction layer or in FIG. 6a to FIG. 6c according to actual needs.

In the aforesaid embodiments, the OAs of the current confinement layers, such as the first OA 510, the second OA 530, the third OA 550, the fourth OA 570, the fifth OA 590, etc., are basically the portions of the current confinement layers that are not insulated. The insulation process may be appropriate insulation processes such as an oxidation process, an ion implantation process or an etching process. In principle, the insulation process is performed from the sides of the multi-layer structure to form the insulation portion of each current confinement layer. The size of the area of each OA can be determined by the oxidation process or the ion implantation process.

In general, the size of the OA is related to the parameters of the oxidation process, such as oxidation time or oxidation rate, etc. The oxidation rate is related to the material or material composition of each current confinement layer or the thickness of each current confinement layer. As such, if the current confinement layers need to form OAs of different sizes, different materials may be used for different current confinement layers, the same material may be used for different current confinement layers but the material composition are different, or the thicknesses of the current confinement layers are different.

In addition, the mesa type process or the non-planar type process may also be a factor that determines the size of an OA. In terms of mesa type process, the insulation process is carried out from the outer side of the mesa. If the mesa is probably narrow on the top and wide at the bottom (such as a trapezoid or ladder shape) or wide on the top and narrow at the bottom (not shown), even if the materials, material composition and thicknesses of current confinement layers are the same, that is, even under the same oxidation rate, the insulation portions of the current confinement layers will be almost the same, but the size of the OAs are different.

If the mesa is as shown in FIG. 1a, under the condition that the diameters of the upper or lower half of the mesa are approximately the same, if the areas of OAs of the current confinement layers are to be as consistent as possible, the materials, material composition and thicknesses of the current confinement layers can be the same. In this way, under the same oxidation rate, the areas of the current confinement layers may be more consistent.

For non-planar type process, multiple holes are formed in the multi-layer structure by wet etching or dry etching such that the holes are distributed in different positions of the current confinement layers. The insulation process is carried out by oxidation from the holes and oxidizing diffusion around. According to the actual need, the ion implantation process can be used after the oxidation process. The portions that are not subjected to the insulation process are the OAs at the end. Hence, the areas of the OAs are mainly determined or adjusted by controlling the number of holes, the distribution of holes or the ion implantation process such that the area of the OAs are significantly different or the areas of the OAs may be more consistent.

Without affecting the carrier confinement and optical confinement of the active layers, the insulation portions of the current confinement layers in the active region may be as small as possible, such as smaller than the insulation portions of the current confinement layers outside the active region. The less the insulation portions of the current confinement layers in the active region are, the less stress and defects in the active region it generates. The stress in the active region is smaller or there are fewer defects generated in the active region such that it is less likely to affect the reliability of a VCSEL. Preferably, the OAs of the current confinement layers are substantially circular, the OAs of the current confinement layers may be in the center regions of the current confinement layers, or the OAs of the current confinement layers correspond to each other.

The insulating region formed by the oxidation process can also improve the optical confinement of a VCSEL due to the change of the refractive index of the insulated portion of the current confinement layer and improve the performance of the VCSEL.

In some embodiments, the substrate is a GaAs substrate or a Ge substrate.

In some embodiments, the material of the current confinement layer has the characteristic of being easily oxidized. Preferably, the material of the current confinement layer contains aluminum or other easily oxidized materials, such as AlGaAs, AlGaAsP, AlAs, AlAsP, AlAsSb or AlAsBi. Specifically, when the current confinement layer of the VCSEL comprises a compound containing phosphorus (P) such as AlAsP (or AlGaAsP), the insulation rate of the current confinement layer will not be too fast, thus enhancing reproducibility. Additionally, the divergence angle of the VCSEL is also smaller.

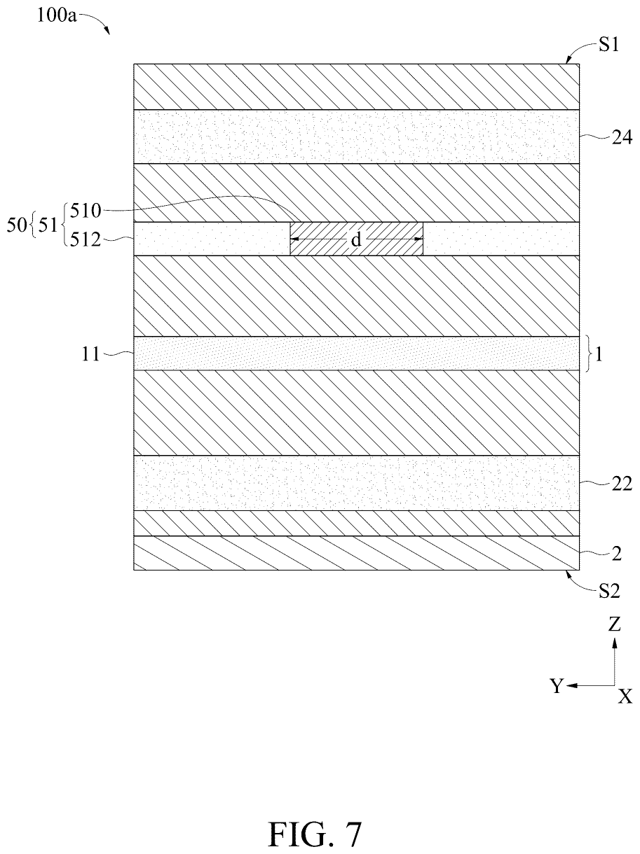

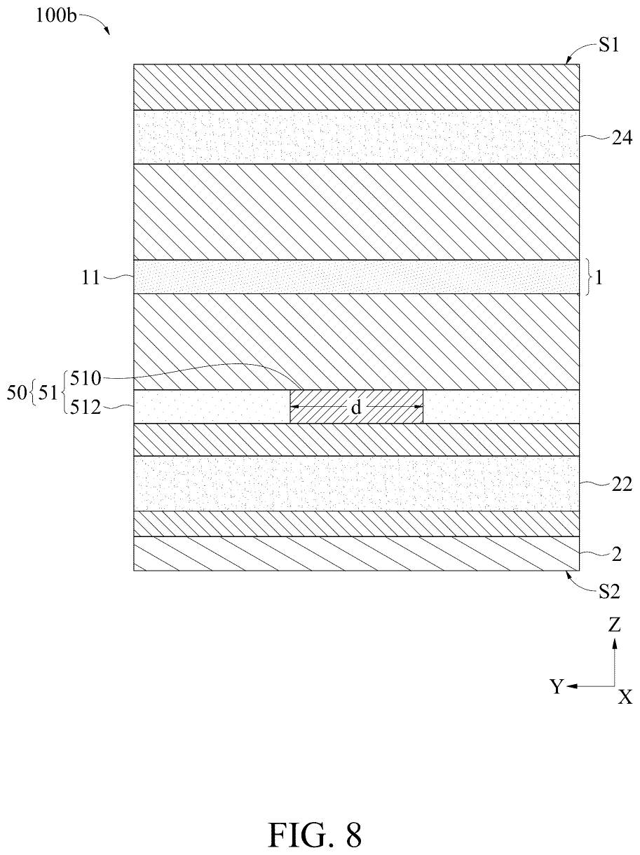

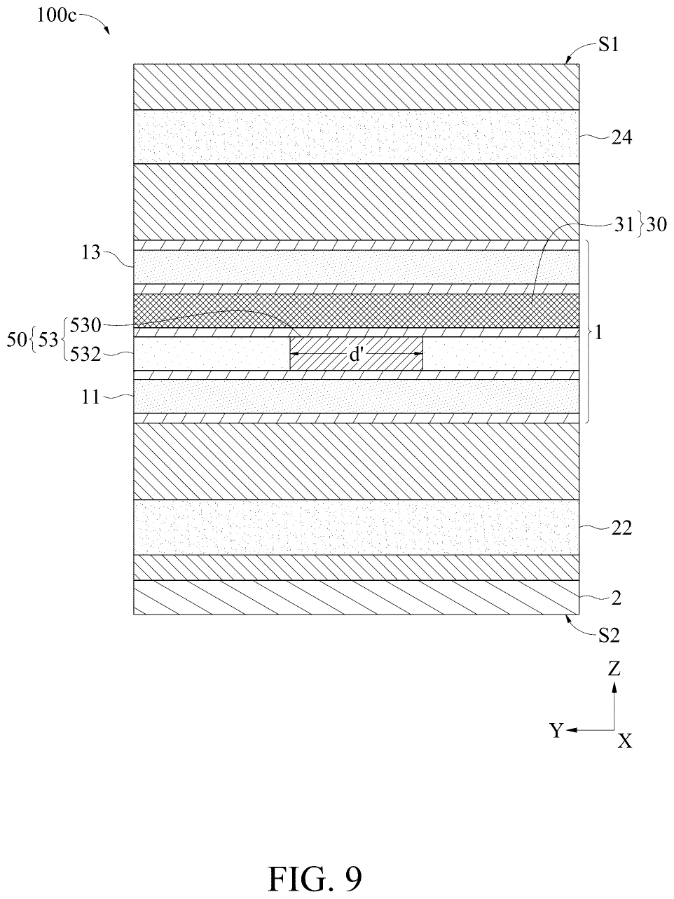

In addition, according to some embodiments, the number of the current confinement layer is able to be limited to one. Specifically, please refer to FIG. 7, FIG. 8, and FIG. 9. FIG. 7, FIG. 8, and FIG. 9 respectively illustrate schematic views of VCSELs 100a, 100b, 100c according to some embodiments. In FIG. 7 and FIG. 8, the VCSELs 100a, 100b respective comprise a substrate 2, a lower DBR layer 22, an active region 1, an upper DBR layer 24, and a current confinement layer 50 (e.g., a first current confinement layer 51). In FIG. 9, the VCSEL 100c comprises a substrate 2, a lower DBR layer 22, an active region 1, an upper DBR layer 24, and a current confinement layer 50 (e.g., a second current confinement layer 53).

For example, in FIG. 7, the current confinement layer 50 (e.g., the first current confinement layer 51) is below the upper DBR layer 24 (e.g., between the upper DBR layer 24 and the active region 1, or in the upper DBR layer). Alternatively, for another example, in FIG. 8, the current confinement layer 50 (e.g., the first current confinement layer 51) is above the lower DBR layer 22 (e.g., between the lower DBR layer 22 and the active region 1, or in the lower DBR layer). In contrast, for another example, in FIG. 9, the current confinement layer 50 (e.g., the second current confinement layer 53) is inside the active region 1 (e.g., between the first tunnel junction 31 and the first active layer 11).

The current confinement layer 50 (e.g., the first current confinement layer 51, the second current confinement layer 53, or both of the current confinement layers 51, 53) comprises a compound containing phosphorus (P); preferably, the compound containing phosphorus is a ternary compound or a quaternary compound, and the ternary compound or the quaternary compound at least contains phosphorus, enabling the subsequent insulation treatment to be more desirably conducted on a part of the current confinement layer 50.

For example, the ternary compound may be an AlAsP compound or a compound containing an AlAsP compound, and the quaternary compound may be an AlGaAsP compound. Hence, after the insulation process is conducted on a part of the current confinement layer 50, the current confinement layer 50 (e.g., the first current confinement layer 51) may have an insulating region (e.g., the first insulating region 512) that is treated by an insulation process and a non-insulating region (e.g., the first non-insulating region (i.e. the first OA 510)) that is not treated by an insulation process. The term “insulating region” used herein should be interpreted as a region of the current confinement layer 50 with higher electrical resistance (i.e., apparently higher than the electrical resistance of the non-insulating region (e.g., the first non-insulating region (i.e. the first OA 510)). Since the non-insulating region (e.g., the non-insulating region (i.e. the first OA 510)) has a lower electrical resistance, and thus the non-insulating region may be considered as the aforementioned optical aperture (i.e., OA).

Furthermore, the ternary compounds used herein, in addition to the three elements, may also include other trace elements beyond the three elements. For example, when adjacent to an AlGaAs semiconductor layer, the AlAsP semiconductor layer often shows trace elements of Ga in the analysis results of Secondary Ion Mass Spectrometer (SIMS). Similarly, if adjacent layers of the AlAsP semiconductor layer contain other elements such as In, Sb, etc., the AlAsP semiconductor layer may also show elements like In, Sb, etc., in the analysis results of SIMS. Additionally, besides being influenced by adjacent semiconductor layers, if the AlAsP semiconductor layer is relatively thin, in the quantitative analysis of SIMS (considering measurement errors), the phosphorus (P) content of the AlAsP semiconductor layer may significantly differ from the actual phosphorus content, possibly being lower than the actual phosphorus content.

In some embodiments, the current confinement layer 50 comprises an AlAsP compound (or an AlGaAsP compound). In these embodiments, since the current confinement layer 50 (e.g., the first current confinement layer 51 as shown in FIG. 7) comprises an AlAsP compound (or an AlGaAsP compound), the insulation process of the current confinement layer 50 would be much more stable (as compared with the oxidation rate of AlAs, the oxidation rate of AlAsP (or AlGaAsP) is slower) and much easier to be controlled, and thus area or shape of the OAs of the VCSEL would “much more consistent with each other”.

In particular, when the current confinement layer 50 (e.g., the first current confinement layer 51) comprises an AlAsP compound (or an AlGaAsP compound), and the single current confinement layer 50 is disposed between the active region 1 and the upper DBR layer 24 (or between the active region 1 and the lower DBR layer 22), only the single current confinement layer 50 (e.g., the first current confinement layer 51) is needed to have the VCSEL to achieve a smaller divergence angle for the VCSEL. Preferably, when the phosphorus content in the AlAsP compound (or the AlGaAsP compound) is within a proper specific range, the insulation process of the current confinement layer 50 can be much more stable and much easier to be controlled, the reproducibility of the aperture in the current confinement layer between various batches of the VCSEL production is improved. Furthermore. In addition, the divergence angle of the VCSEL can be smaller and the stress of the VCSEL can also be reduced. Hence, as for multiple current confinement layers (e.g., the first current confinement layer 51 and the second current confinement layer 53 as shown in FIG. 1c), those OAs (e.g., 510 and 530 in FIG. 1c) in the same VCSEL can have a much higher shape similarity. In addition, those OAs between different VCSELs can also have a much higher shape similarity. Additionally, the VCSEL comprising multiple current confinement layers can also possess a much smaller divergence angle.

As mentioned above, compared with the divergence angle of the traditional VCSEL or the VCSEL including the current confinement layer(s) manufactured by materials other than the AlAsP compound (or the AlGaAsP compound), the VCSELs (e.g., 100a, 100b as shown in FIG. 7 and FIG. 8) according to some embodiments of the invention can possess a much smaller divergence angle (e.g., 13.297 degree, which will be described in detail in the following TABLE 1 and TABLE 2). Accordingly, the VCSELs (e.g., 100a, 100b) can be applied to a broader application due to the reduced divergence angle.

In some embodiments related to the controllable and more stable oxidation rate, a molar percentage of the phosphorus content in the compound containing phosphorus is greater than 0% and less than or equal to 30%; or greater than 0% and less than or equal to 20%; or greater than 0% and less than or equal to 15%. For example, in some embodiments, the current confinement layer 50 (e.g., the first current confinement layer 51) comprises an AlAsP compound which may be represented by AlAs₁₋ₓPₓ, wherein the molar ratio of As over P is (1−x):x, and for example, 0<x≤0.3 (or 0<x≤0.20; or 0<x≤0.15; or 0<x≤0.12; or 0<x≤0.10; or 0<x≤0.10, 0<x≤0.08, or 0<x≤0.06). Within the above range, the oxidation rate of AlAs₁₋ₓPₓ can be much closer to the oxidation rate of AlGaAs; meanwhile, the divergence angle of AlAs₁₋ₓPₓ can be much smaller, and the stress of the VCSEL would not be too large. For example, the first current confinement layer 51 as shown in FIG. 7 (or the second current confinement layer 53 as shown in FIG. 1c) comprise an AlAs₁₋ₓPₓ compound and the x can be approximately 0.01, 0.02, 0.03, 0.04, 0.05, 0.06, 0.07, 0.08, 0.09, 0.10, 0.11, 0.12, 0.13, 0.14, 0.15, 0.16, 0.17, 0.18, 0.19, 0.20, 0.21, 0.22, 0.23, 0.24, 0.25, 0.26, 0.27, 0.28, 0.29, or else value greater than 0 and less than or equal to 0.30. For example, the specific ranges can include 0.02<x≤0.12, 0.2<x≤0.10, 0.2<x≤0.08, 0.2<x≤0.06, or other specific ranges. If x is not within the above range (e.g., (apparently) greater than 0.3), the AlAs₁₋ₓPₓ compound having the corresponding phosphorus content would not show a negative effect as compared to those AlAs₁₋ₓPₓ compound with its x within the above range.

In some embodiments, the current confinement layer 50 (e.g., the first current confinement layer 51) does not comprise an AlGaAs compound. It is surprising that, when the current confinement layer (e.g., 16) comprises an AlGaAs compound, the VCSEL has a larger divergence angle, which is commonly considered undesirable. In other words, when the VCSEL has the current confinement layer comprising an AlGaAs compound, the object of some embodiments of the invention (i.e., providing a smaller divergence angle) would not be achieved.

From above, in some embodiments, for example, in FIG. 7 and FIG. 8, the VCSELs 100a, 100b comprising a single current confinement layer (e.g., the first current confinement layer 51) and a single active layer (e.g., the first active layer 11) could have its current confinement layer 50 manufactured by a more stable and much easier-to-control oxidation rate, and the obtained VCSELs (e.g., 100a or 100b) can also provide a much smaller divergence angle.

The above effects can be illustrated by the following Examples A to D, where the insulating process of those current confinement layers according to some embodiments of the invention or the traditional current confinement layers are all conducted by the oxidation treatment.

### [Example A] Comparison of Divergence Angle-VCSEL Comprising a Single Active Layer and a Single Current Confinement Layer (as Compared with the Traditional VCSEL Comprising a Current Confinement Layer Containing AlGaAs)

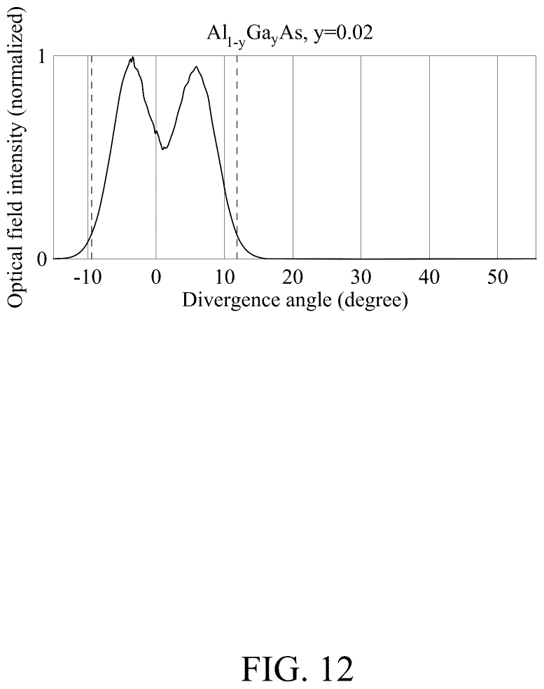

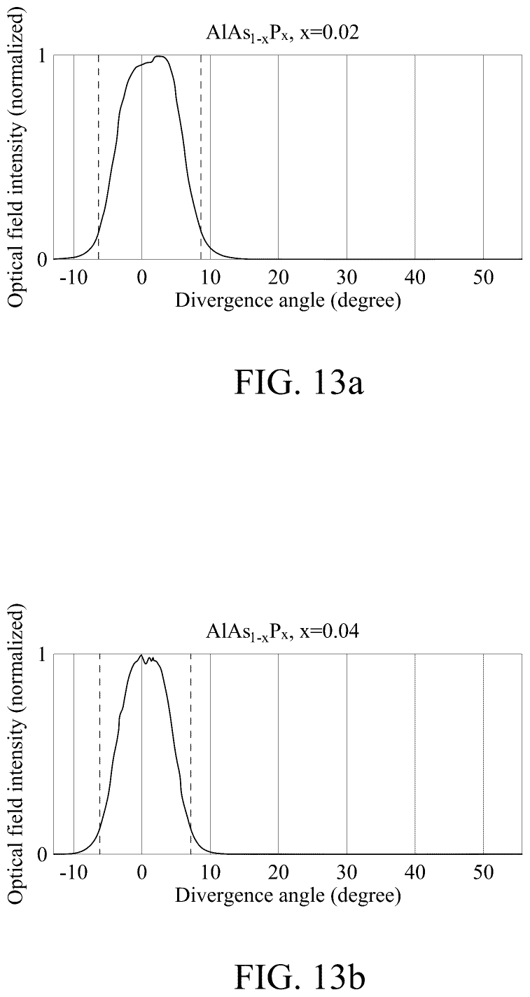

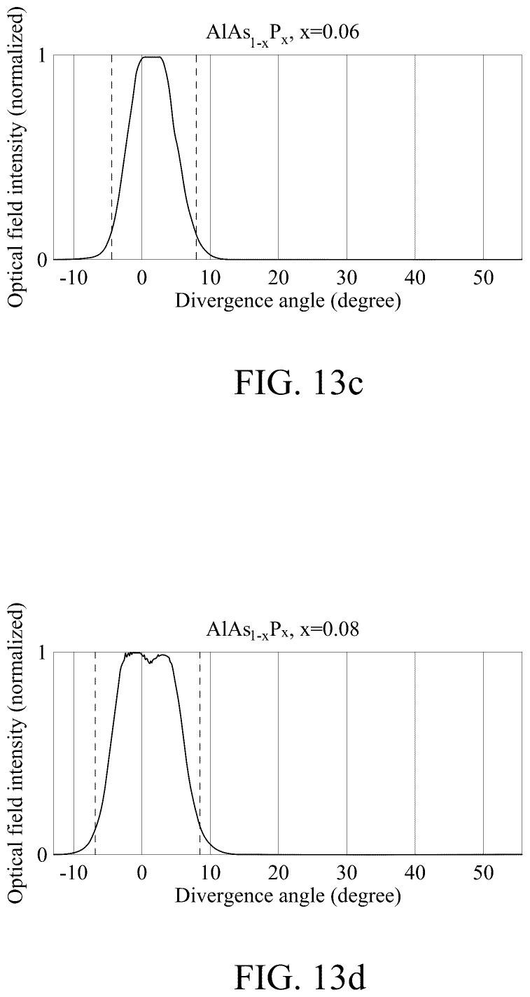

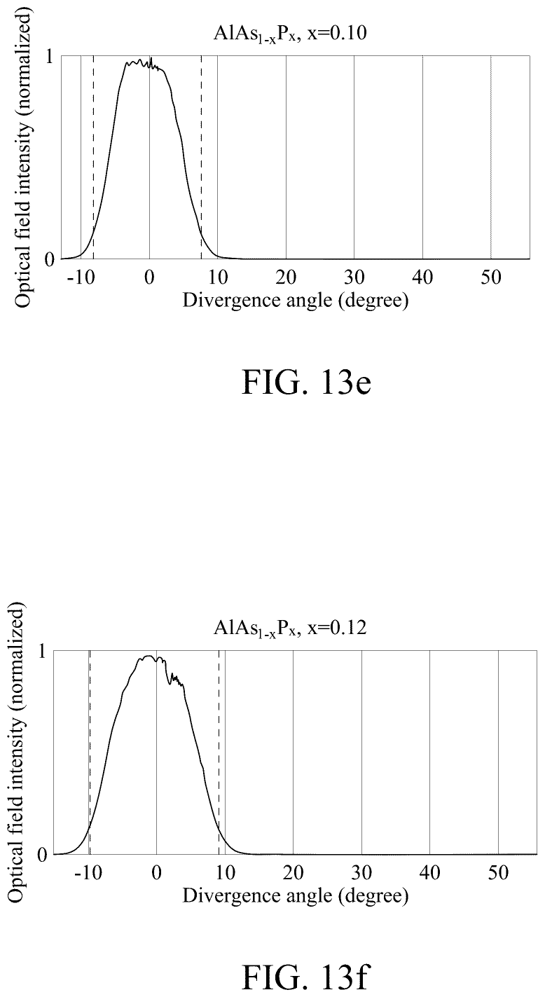

Please refer to FIG. 7, FIG. 12, and FIG. 13a to FIG. 13f. FIG. 12 illustrates a far field profile of the traditional VCSEL (with is current confinement layer containing an AlGaAs compound) based on the structure of the VCSEL 100a shown in FIG. 7; FIG. 13a to FIG. 13f illustrate far field profiles of the VCSELs 100a shown in FIG. 7 (with its current confinement layers containing AlAs₁₋ₓPₓ compounds, and x=0.02, 0.04, 0.06, 0.08, 0.10, and 0.12, respectively). The OA diameters of the current confinement layer 50 shown in FIG. 7 and the traditional VCSEL were all approximately 8 μm, and the far field profiles thereof were all measured and obtained at a continuous wave (CW) bias current of 10 mA. According to the far field profiles shown in FIG. 12 and FIG. 13a to FIG. 13f, the divergence angles corresponding to each VCSEL at 1/e2 width are summarized in the following TABLE 1.

TABLE 1
Comparison of Divergence Angle-VCSEL comprising a single
active layer and a single current confinement layer
(as compared with the traditional VCSEL comprising
a current confinement layer containing AlGaAs)

| | | | Divergence |
|---|---|---|---|
| | | | angle |
| | Current confinement layer | | (degree) |
| The traditional | containing an | y = 0.02 | 20.985 |
| VCSEL | Al_{1-y}Ga_{y}As compound | | |
| Embodiments of | containing an | x = 0.02 | 13.297 |
| the invention | AlAs₁₋ₓPₓ compound | x = 0.04 | 13.814 |
| | | x = 0.06 | 14.728 |
| | | x = 0.08 | 15.263 |
| | | x = 0.10 | 17.744 |
| | | x = 0.12 | 18.770 |

From the above TABLE 1, FIG. 12, and FIG. 13a to FIG. 13f, as for the VCSEL having a single active layer and a single current confinement layer, the divergence angle of the traditional VCSEL (with its current confinement layer containing an AlGaAs compound; for example, Al_{1-y}Ga_{y}As compound and y=0.02) was 20.985 degree; while the divergence angles of the VCSELs 100a according to some embodiments of the invention (with each current confinement layer containing AlAs_{0.98}P_{0.02} (i.e., x=0.02), AlAs_{0.96}P_{0.04} (i.e., x=0.04), AlAs_{0.94}P_{0.06} (i.e., x=0.06), AlAs_{0.92}P_{0.08} (i.e., x=0.08), AlAs_{0.90}P_{0.10} (i.e., x=0.10), and AlAs_{0.88}P_{0.12} (i.e., x=0.12)) were 13.297 degree, 13.814 degree, 14.728 degree, 15.263 degree, 17.744 degree, and 18.770 degree, respectively. This clearly shows that the divergence angles for the VCSELs with an AlAsP-based current confinement layer are significantly smaller as compared to those with an AlGaAs-based current confinement layer. Accordingly, since the current confinement layer 50 (e.g., the first current confinement layer 51) contains the specific AlAsP compound (or AlGaAsP compound), a smaller divergence angle can be achieved according to some embodiments of the invention as compared with that of the traditional current confinement layer containing an AlGaAs compound (such as an Al_{0.98}Ga_{0.02}As compound).

Hence, compared with the traditional VCSEL (with its current confinement layer containing an AlGaAs compound), even though the VCSEL (e.g., 100a) according to some embodiments comprises a single active layer (e.g., 11) and a single current confinement layer (e.g., 51), a smaller divergence angle can be still provided by the VCSEL (e.g., 100a).

### [Example B] Comparison of Oxidation Rate and Divergence Angle-VCSEL Comprising a Single Active Layer and a Single Current Confinement Layer (as Compared with the Traditional VCSEL Comprising a Current Confinement Layer Containing AlAs)

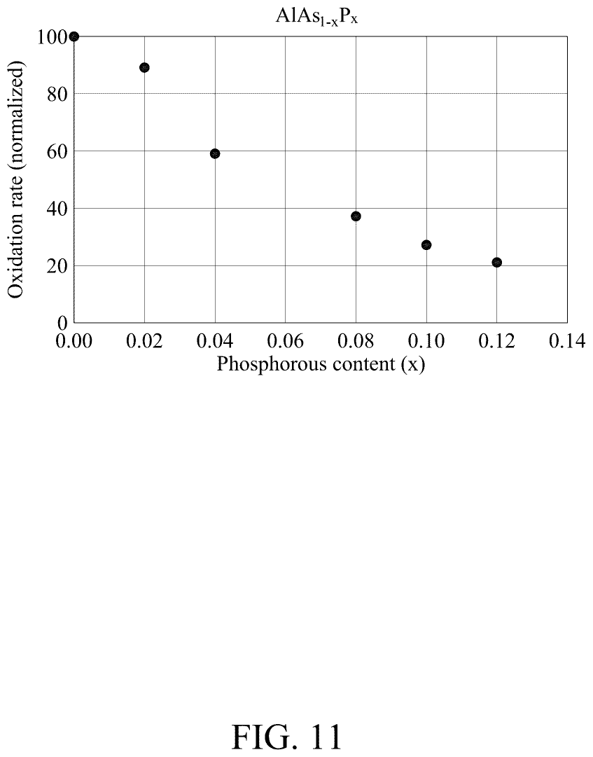

Please refer to FIG. 7 and FIG. 11. FIG. 11 illustrates oxidation rates of the first current confinement layer 51 shown in FIG. 7 (which comprises an AlAs₁₋ₓPₓ compound) and the traditional current confinement layer (which comprises an AlAs compound). As shown in FIG. 7, the VCSEL 100a comprises a single active layer (i.e., the first active layer 11) and a single current confinement layer (i.e., the first current confinement layer 51), and the single current confinement layer is between the upper DBR layer 24 and the active region 1. The first current confinement layer 51 contains an AlAs₁₋ₓPₓ compound with the x being 0, 0.02, 0.04, 0.08, 0.10, and 0.12, respectively, when x equal to 0, the first current confinement layer 51 is considered the traditional current confinement layer containing an AlAs compound. Furthermore, the oxidation rate of the traditional current confinement layer (which contains an AlAs compound) is taken as the standard oxidation rate (i.e., 100%, which is regarded as excessively fast oxidation rate), the oxidation rates according to some embodiments of the invention are normalized, and the resulting oxidation rates are further listed in the following TABLE 2. When the resulting oxidation rate (normalized) is less than the standard oxidation rate (i.e., 100%), it indicates that the oxidation rate (normalized) corresponding to some embodiments of the invention is less than the oxidation rate of the traditional current confinement layer containing an AlAs compound (i.e., x=0.0) and thus slower than the traditional oxidation rate of AlAs.

TABLE 2
Comparison of Oxidation Rate and Divergence Angle-VCSEL
comprising a single active layer and a single current confinement
layer (as compared with the traditional VCSEL comprising
a current confinement layer containing AlAs)

| | | | Divergence | Oxidation |
|---|---|---|---|---|
| | Current confinement | | angle | rate |
| | layer | | (degree) | (normalized) |
| The traditional | containing an AlAs | | 14.380 | 100% |
| VCSEL | compound | | | |
| Embodiments | containing an | x = 0.02 | 13.297 | 89 |
| of the | AlAs₁₋ₓPₓ | x = 0.04 | 13.814 | 59 |
| invention | compound | x = 0.08 | 15.263 | 37 |
| | | x = 0.10 | 17.744 | 27 |
| | | x = 0.12 | 18.770 | 21 |

From the above TABLE 2 and FIG. 11, when the x in the AlAs₁₋ₓPₓ (i.e., the phosphorus content) gradually increased to 0.02, 0.04, 0.08, 0.10, and 0.12, the resulting oxidation rates (normalized) were 89, 59, 37, 27, and 21, respectively, which showed a trend of the oxidation rates that are gradually-reduced and more controllable. Hence, the phosphorus content in AlAs₁₋ₓPₓ would indeed influence the oxidation rates, and the phosphorus content should be limited at least within the above specific range to show an oxidation rate that is more stable and much easier to control according to some embodiments.

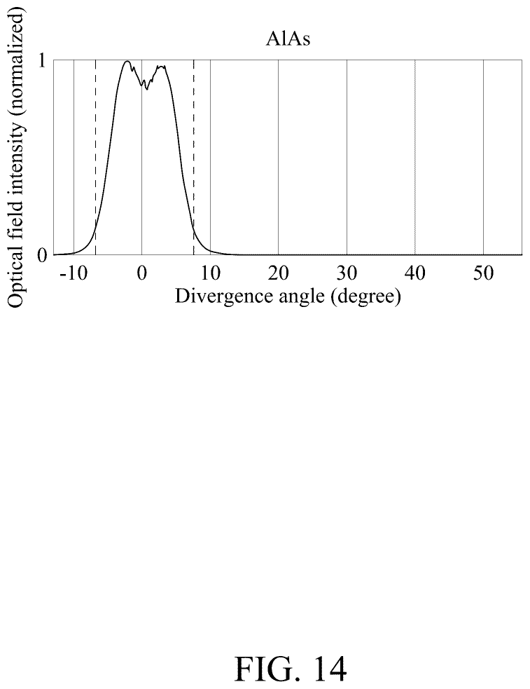

Next, please further refer to FIG. 7, FIG. 13a to FIG. 13f, and FIG. 14. FIG. 14 illustrates a far field profile of the traditional VCSEL (with its current confinement layer containing an AlAs compound) based on the structure of the VCSEL 100a shown in FIG. 7. The OA diameters of the current confinement layer 50 shown in FIG. 7 and the traditional VCSEL were all approximately 8 μm, and the far field profiles thereof were all measured and obtained at a continuous wave (CW) bias current of 10 mA. According to the far field profiles shown in FIG. 13a to FIG. 13f and FIG. 14, the divergence angles corresponding to each VCSEL at 1/e2 width are summarized in the above TABLE 2.

From the above TABLE 2, FIG. 13a to FIG. 13f, and FIG. 14, as for the VCSEL having a single active layer and a single current confinement layer, the divergence angle of the traditional VCSEL (with its current confinement layer containing an AlAs compound) was 14.380 degree; while the divergence angles of the VCSELs 100a according to some embodiments of the invention (with each current confinement layer containing AlAs_{0.98}P_{0.02} (i.e., x=0.02), AlAs_{0.96}P_{0.04} (i.e., x=0.04), AlAs_{0.94}P_{0.06} (i.e., x=0.06), AlAs_{0.92}P_{0.08} (i.e., x=0.08), AlAs_{0.90}P_{0.10} (i.e., x=0.10), and AlAs_{0.88}P_{0.12} (i.e., x=0.12) were 13.297 degree, 13.814 degree, 14.728 degree, 15.263 degree, 17.744 degree, and 18.770 degree. Therefore, it can be seen that some embodiments of the present invention can have a small divergence angle comparable to that of conventional AlAs-containing compounds.

Hence, compared with the traditional VCSEL (with its current confinement layer containing an AlAs compound), even though the VCSEL (e.g., 100a) according to some embodiments comprises a single active layer (e.g., 11) and a single current confinement layer (e.g., 51), a smaller divergence angle can be still provided by the VCSEL (e.g., 100a).

### [Example C] Comparison of Divergence Angle-VCSEL Comprising Multiple Active Layers and Multiple Current Confinement Layers (i.e., Two Current Confinement Layers) (as Compared with the Traditional VCSEL Comprising a Current Confinement Layer Containing AlGaAs)

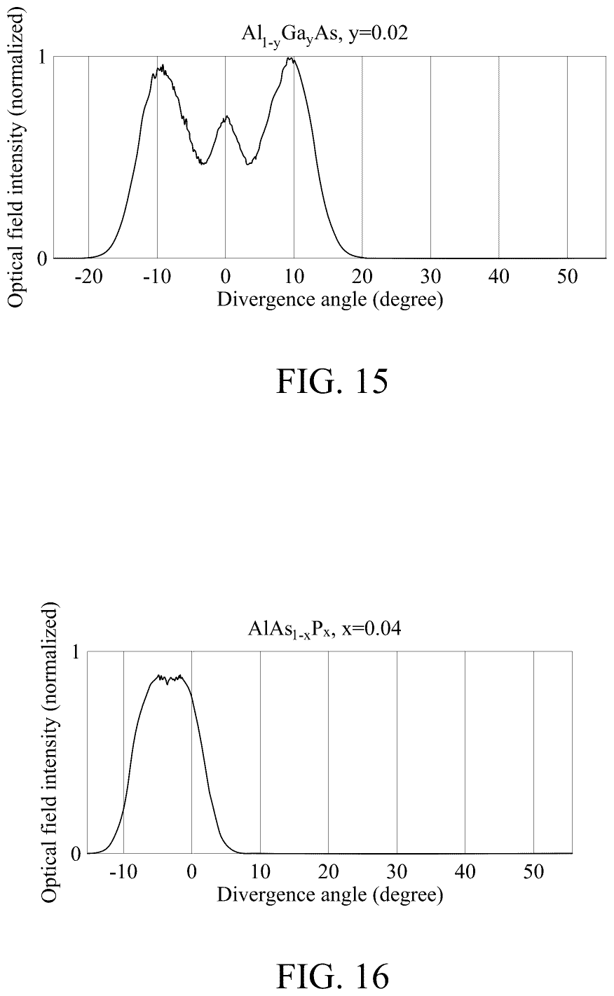

Please refer to FIG. 1c, FIG. 15, and FIG. 16. FIG. 15 illustrates a far field profile of the traditional VCSEL (with its current confinement layer containing an AlGaAs compound (for example, an Al_{1-y}Ga_{y}As compound and y=0.02)) based on the structure of the VCSEL shown in FIG. 1c; FIG. 16 illustrates a far field profile of the VCSEL shown in FIG. 1c (with its current confinement layer containing an AlAs₁₋ₓPₓ compound and x=0.04). The OA diameters of the current confinement layer 50 shown in FIG. 1c and the traditional VCSEL were all approximately 10 μm, and the far field profiles thereof were all measured and obtained at a continuous wave (CW) bias current of 7 mA. According to the far field profiles shown in FIG. 15 and FIG. 16, the divergence angles corresponding to each VCSEL at 1/e2 width are summarized in the following TABLE 3.

TABLE 3
Comparison of Divergence Angle-VCSEL comprising multiple active
layers and multiple current confinement layers (i.e., two current
confinement layers) (as compared with the traditional VCSEL
comprising a current confinement layer containing AlGaAs)

| | | | Divergence |
|---|---|---|---|
| | | | angle |
| | Current confinement layer | | (degree) |
| The traditional | containing an | y = 0.02 | 26.257 |
| VCSEL | Al_{1-y}Ga_{y}As compound | | |
| Embodiments of | containing an | x = 0.04 | 14.786 |
| the invention | AlAs₁₋ₓPₓ compound | | |

From the above TABLE 3, FIG. 15, and FIG. 16, as for the VCSEL having multiple active layers and multiple current confinement layers (i.e., two current confinement layers), the divergence angle of the traditional VCSEL (with its current confinement layers containing an AlGaAs compound; for example, Al_{1-y}Ga_{y}As compound and y=0.02)) was 26.257 degree; while the divergence angle of the VCSEL according to some embodiments of the invention (with the current confinement layer containing AlAs_{0.96}P_{0.04} (i.e., x=0.04)) was 14.786 degree, which was apparently less than that of the traditional VCSEL with its current confinement layer containing an AlGaAs compound (for example, an Al_{1-y}Ga_{y}As compound and y=0.02). Accordingly, since the current confinement layers 50 (e.g., the first current confinement layer 51 and the second current confinement layer 53) contain the specific AlAsP compounds (or AlGaAsP compounds), a smaller divergence angle can be provided according to some embodiments of the invention as compared with that of the traditional current confinement layers containing AlGaAs compounds (such as Al_{0.98}Ga_{0.02}As compounds).

Hence, compared with the traditional VCSEL (with its current confinement layer containing AlGaAs compounds), even though the VCSEL in some embodiments comprises multiple active layers (e.g., 11 and 13 as shown in FIG. 1c) and multiple current confinement layers (e.g., 51 and 53 as shown in FIG. 1c), they can still achieve a smaller divergence angle.

### [Example D] Comparison of Divergence Angle-VCSEL Comprising Multiple Active Layers and Multiple Current Confinement Layers (i.e., Six Current Confinement Layers) (as Compared with the Traditional VCSEL Comprising a Current Confinement Layer Containing AlGaAs)

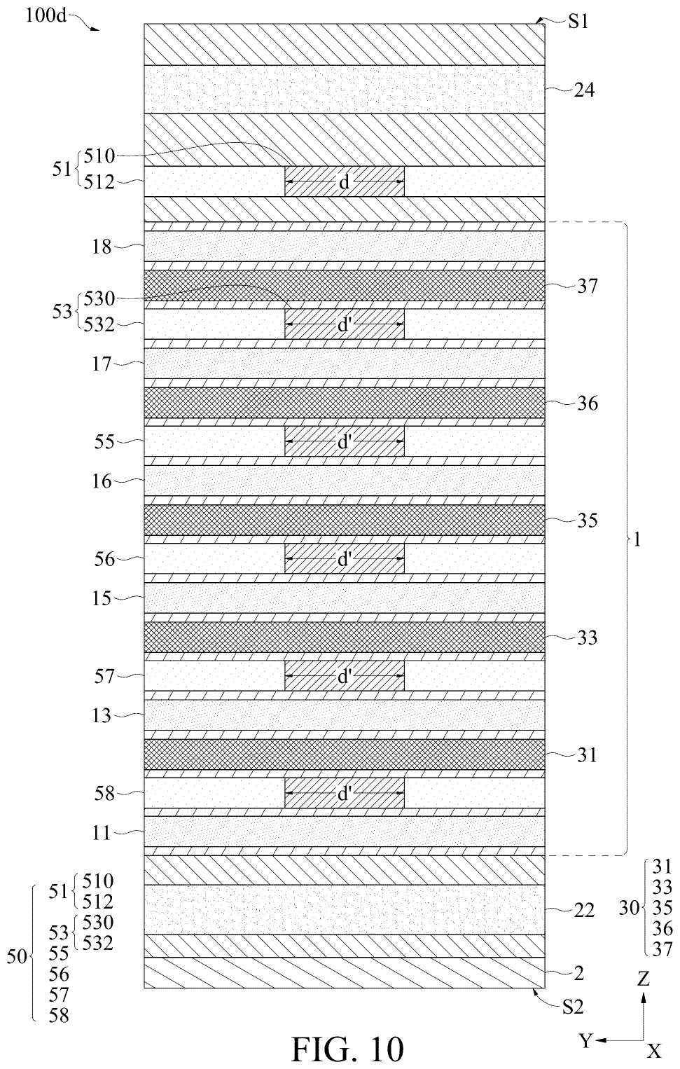

Please refer to FIG. 10. FIG. 10 illustrates a schematic view of a VCSEL 100d according to some embodiments. In FIG. 10, the VCSEL 100d comprises six active layers and six current confinement layers, wherein five among the six current confinement layers (i.e., the second current confinement layer 53, the third current confinement layer 55, the fourth current confinement layer 56, the fifth current confinement layer 57 and the sixth current confinement layer 58 are inside the active region 1 and each of the current confinement layers is between any two of the active layers; and the remaining current confinement layer (i.e., the first current confinement layer 51) is between the upper DBR layer 24 and the active region 1. After each of the current confinement layers 51, 53, 55, 56, 57, 58 are treated by the oxidation treatment, an insulating region and a non-insulating region corresponding to each of the current confinement layers would be then respectively formed, and the detailed embodiments thereof may be referred to the aforementioned embodiments, which is thus not further described in detail herein.

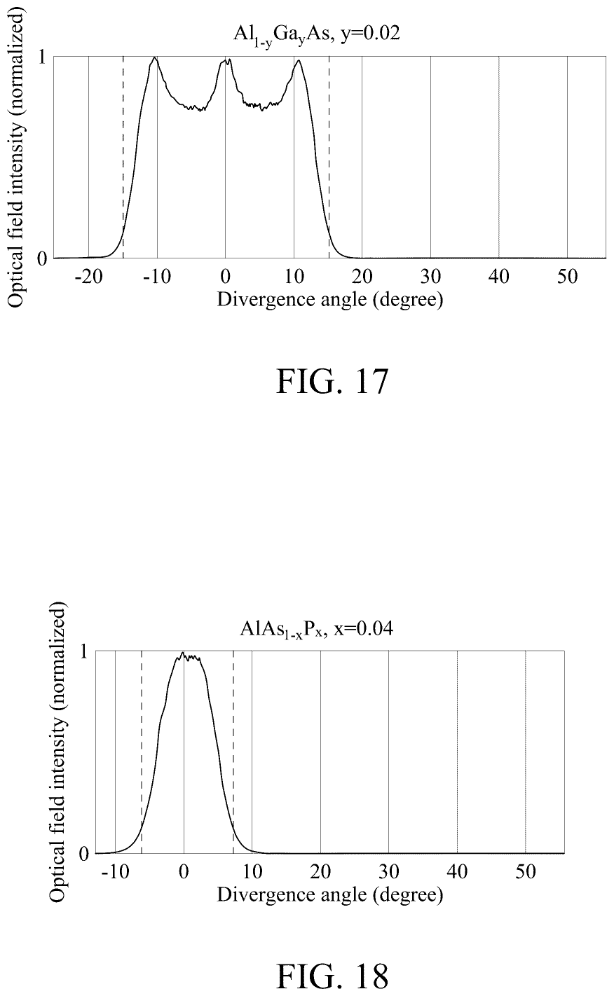

Please further refer to FIG. 10, FIG. 17, and FIG. 18. FIG. 17 illustrates a far field profile of the traditional VCSEL (with its current confinement layer containing an AlGaAs compound (for example, an Al_{1-y}Ga_{y}As compound and y=0.02)) based on the structure of the VCSEL 100d shown in FIG. 10; FIG. 18 illustrates a far field profile of the VCSEL 100d shown in FIG. 10 (with its current confinement layers 51, 53, 55, 57, 58, 59 containing AlAs₁₋ₓPₓ compounds and x=0.04). The OA diameters of the current confinement layers 51, 53, 55, 56, 57, 58 shown in FIG. 10 were all approximately 20 μm, and the far field profiles thereof were all measured and obtained at a continuous wave (CW) bias current of 7 mA. According to the far field profiles shown in FIG. 17 and FIG. 18, the divergence angles corresponding to each VCSEL at 1/e2 width are summarized in the following TABLE 4.

TABLE 4
Comparison of Divergence Angle-VCSEL comprising multiple active
layers and multiple current confinement layers (i.e., six current
confinement layers) (as compared with the traditional VCSEL comprising
multiple current confinement layers containing AlGaAs)

| | | | Divergence |
|---|---|---|---|
| | | | angle |
| | Current confinement layer | | (degree) |
| The traditional | containing an | y = 0.02 | 29.986 |
| VCSEL | Al_{1-y}Ga_{y}As compound | | |
| Embodiments of | containing an | x = 0.04 | 12.264 |
| the invention | AlAs₁₋ₓPₓ compound | | |

From the above TABLE 4, as for the VCSEL having multiple active layers and multiple current confinement layers (i.e., six current confinement layers), the divergence angle of the traditional VCSEL (with its current confinement layers containing an AlGaAs compound; for example, Al_{1-y}Ga_{y}As compound and y=0.02)) was 29.986 degree; while the divergence angle of the VCSEL according to some embodiments of the invention (with the current confinement layer containing AlAs_{0.96}P_{0.04} (i.e., x=0.04)) was 12.264 degree, which was apparently much less than that of the traditional VCSEL with its current confinement layer containing an AlGaAs compound (for example, an Al_{1-y}Ga_{y}As compound and y=0.02). Accordingly, since the current confinement layers 50 (e.g., the current confinement layers 51, 53, 55, 56, 57, 58) contain the specific AlAsP compounds (or AlGaAsP compounds), a smaller divergence angle can be provided according to some embodiments of the invention as compared with that of the traditional current confinement layers containing AlGaAs compounds (such as Al_{0.98}Ga_{0.02}As compounds).

Hence, compared with the traditional VCSEL (with its current confinement layer containing AlGaAs compounds), even though the VCSEL (e.g., 100d) according to some embodiments comprises multiple active layers (e.g., 11, 13, 15, 16, 17, 18 as shown in FIG. 10) and multiple current confinement layers (e.g., 51, 53, 55, 56, 57, 58 as shown in FIG. 10), a smaller divergence angle can be still provided by the VCSEL (e.g., 100d).

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A vertical cavity surface emitting laser diode (VCSEL) comprising:
a substrate;
a lower DBR layer on the substrate;
an active region on the lower DBR layer and comprising two active layers;
an upper DBR layer on the active region; and
a current confinement layer between the two active layers and comprising an AlAsP compound or an AlGaAsP compound, wherein the current confinement layer has an insulating region and a non-insulating region surrounded by the insulating region, wherein a molar percentage of a phosphorus content in the compound containing phosphorus (P) is greater than 0% and less than or equal to 30%.

2. The VCSEL according to claim 1, wherein the molar percentage of the phosphorus content in the compound containing phosphorus is greater than 0% and less than or equal to 20%.

3. The VCSEL according to claim 1, wherein the molar percentage of the phosphorus content in the compound containing phosphorus is greater than 0% and less than or equal to 15%.

4. The VCSEL according to claim 1, wherein the active region comprises a tunnel junction between the two active layers, and the current confinement layer is between the tunnel junction and any active layer of the two active layers.

5. The VCSEL according to claim 4, wherein the VCSEL further comprises another current confinement layer outside the active region, and the another current confinement layer comprises a compound containing phosphorus (P) and has an insulating region and a non-insulating region surrounded by the insulating region.

6. The VCSEL according to claim 5, wherein the another current confinement layer is below the upper DBR layer, in the upper DBR layer, in the lower DBR layer, or above the lower DBR layer.

7. The VCSEL according to claim 5, wherein an area of the non-insulating region of the current confinement layer is identical to an area of the non-insulating region of the another current confinement layer.

8. The VCSEL according to claim 5, wherein an area of the non-insulating region of the current confinement layer is not identical to an area of the non-insulating region of the another current confinement layer.

9. The VCSEL according to claim 1, wherein the substrate is a GaAs substrate or a Ge substrate.

10. A vertical cavity surface emitting laser diode (VCSEL) comprising:
a substrate;
a lower DBR layer on the substrate;
an active region on the lower DBR layer;
an upper DBR layer on the active region; and
a current confinement layer outside the active region and comprising an AlAsP compound or an AlGaAsP compound, wherein the current confinement layer has an insulating region and a non-insulating region surrounded by the insulating region, wherein a molar percentage of a phosphorus content in the compound containing phosphorus (P) is greater than 0% and less than or equal to 30%.

11. The VCSEL according to claim 10, wherein the molar percentage of the phosphorus content in the compound containing phosphorus is greater than 0% and less than or equal to 20%.

12. The VCSEL according to claim 10, wherein the molar percentage of the phosphorus content in the compound containing phosphorus is greater than 0% and less than or equal to 15%.

13. The VCSEL according to claim 10, wherein the current confinement layer is below the upper DBR layer, in the upper DBR layer, in the lower DBR layer, or above the lower DBR layer.

14. The VCSEL according to claim 10, wherein:
the active region comprises two active layers; and
the VCSEL further comprises another current confinement layer between the two active layers, and the another current confinement layer comprises an AlAsP compound or an AlGaAsP compound, wherein the another current confinement layer has an insulating region and a non-insulating region surrounded by the insulating region.

15. The VCSEL according to claim 14, wherein the active region comprises a tunnel junction between the two active layers, and the another current confinement layer is between the tunnel junction and any active layer of the two active layers.

16. The VCSEL according to claim 14, wherein an area of the non-insulating region of the current confinement layer is identical to an area of the non-insulating region of the another current confinement layer.

17. The VCSEL according to claim 14, wherein an area of the non-insulating region of the current confinement layer is not identical to an area of the non-insulating region of the another current confinement layer.

18. The VCSEL according to claim 10, wherein the substrate is a GaAs substrate or a Ge substrate.
